(19) United States
(12) Patent Application Publication
(10) Pub. No.: US 2026/0148674 A1
(43) Pub. Date: May 28, 2026

(54) Display Panel and Display Device Including the Same

(71) Applicant: LG Display Co., Ltd., Seoul (KR)

(72) Inventors: Seunghwan Shin, Jeonju-si (KR); Wonho Lee, Paju-si (KR)

(21) Appl. No.: 19/291,918

(22) Filed: Aug. 6, 2025

(30) Foreign Application Priority Data
Oct. 10, 2024 (KR) 10-2024-0137365

(51) Int. Cl. G09G 3/20; G09G 3/3233; H10K 59/131

(52) U.S. Cl. CPC G09G 3/2074; G09G 3/3233; H10K 59/131; G09G 2300/0408; G09G 2300/0426; G09G 2300/0452; G09G 2300/0804; G09G 2300/0852; G09G 2310/0286; G09G 2310/0289; G09G 2310/08; G09G 2320/0223; G09G 2320/0233; G09G 2320/0666; G09G 2330/023

(57) ABSTRACT

Disclosed is a display device that applies a data voltage to three sub-pixels emitting light of the same color being arranged in the same row via a first sub-data line and applies a data voltage to two sub-pixels emitting light of the same color being arranged in the same row via a second sub-data line. To this end, each data line in a display panel divides into a plurality of sub-data lines, and the data voltage is applied to two or three sub-pixels emitting light of the same color being arranged in the same row via a single sub-data line, thereby minimizing RC delay and reducing a manufacturing cost.

### CROSS-REFERENCE TO RELATED APPLICATION

This application claims priority from Republic of Korea Patent Application No. 10-2024-0137365 filed on Oct. 10, 2024, where is hereby incorporated by reference in its entirety.

### BACKGROUND

### Field

The present disclosure relates to a display device, and more particularly, to a display panel having a reduced number of data lines and a display device including the same.

### Description of Related Art

Display devices used in a computer monitor, a television (TV), a mobile phone, or the like include an organic light-emitting display device (OLED) that emits light by itself, and a liquid crystal display device (LCD) that requires a separate light source.

Among these various display devices, the organic light-emitting display device includes a display panel including a plurality of sub-pixels and a driver for driving the display panel. The driver includes a gate driver for supplying a gate signal to the display panel and a data driver for supplying a data voltage. When a signal such as a gate signal and a data voltage is supplied to a sub-pixel of the organic light-emitting display device, the selected sub-pixel may emit light to display an image.

However, in designing the display panel, there is a problem in that the resistor-capacitor (RC) delay increases as the data lines are designed in a bundle manner.

Accordingly, there is a need for a display device that reduces the RC delay by operating a predetermined multiple of sub-pixels emitting light of the same color with one data line.

### SUMMARY

In the related art, there is a problem in that charging characteristics according to implementation of triple rate driving (TRD) cannot be secured due to an increase in RC delay and an increase in time according to double rate driving (DRD) 120 Hz operation. Accordingly, the inventors of the present disclosure have invented a display panel capable of minimizing an increase in the RC delay by 30% or greater by column-inverting a plurality of sub-pixels.

A purpose to be achieved according to an embodiment of the present disclosure is to provide a display panel in which a data line divides into a plurality of sub-data lines, and a data voltage is applied to a predetermined multiple of sub-pixels emitting light of the same color via each sub-data line.

In addition, a purpose to be achieved according to an embodiment of the present disclosure is to provide a display device in which a plurality of sub-data lines is disposed in a display panel such that a data voltage supplied from a data driver is applied to five sub-pixels emitting light of the same color being arranged in the same row via two sub-data lines.

In addition, a purpose to be achieved according to an embodiment of the present disclosure is to provide a display panel in which a plurality of sub-data lines are disposed such that a data voltage is applied to five sub-pixels emitting light of the same color being arranged in the same row via two sub-data lines.

In addition, a purpose to be achieved according to an embodiment of the present disclosure is to provide a display panel in which a plurality of sub-data lines are disposed such that a data voltage is applied to three or two sub-pixels emitting light of the same color being arranged in a first row via a first sub-data line among the plurality of sub-data lines or a data voltage is applied to two or three sub-pixels emitting light of the same color being arranged in a second row via the first sub-data line among the plurality of sub-data lines.

In addition, a purpose to be achieved according to an embodiment of the present disclosure is to provide a display panel for driving two or three sub-pixels emitting light of the same color with one sub-data line.

In addition, a purpose to be achieved according to an embodiment of the present disclosure is to provide a display device including a display panel for operating 2.5 sub-pixels with one sub-data line.

Purposes according to the present disclosure are not limited to the above-mentioned purpose. Other purposes and advantages according to the present disclosure that are not mentioned may be understood based on following description, and may be more clearly understood based on embodiments according to the present disclosure. Further, it will be easily understood that the purposes and advantages according to the present disclosure may be realized using means shown in the claims or combinations thereof.

A display device according to an embodiment of the present disclosure includes a display panel in which each of a plurality of data lines divides into a plurality of sub-data lines, and the data voltage is applied to a plurality of sub-pixels emitting light of the same color via each of the sub-data lines.

In addition, according to an embodiment of the present disclosure, there is provided a display panel in which each of a plurality of data lines for supply the data voltage to the plurality of pixels divides into a plurality of sub-data lines, and the plurality of sub-data lines are disposed such that a data voltage supplied from a data driver is applied to five sub-pixels emitting light of the same color being arranged in the same row via two sub-data lines.

In addition, according to an embodiment of the present disclosure, there is provided a display panel in which the data line divides into a first sub-data line and a second sub-data line.

In addition, according to an embodiment of the present disclosure, there is provided a display device including a display panel in which a data voltage is applied to three sub-pixels among five sub-pixels emitting light of the same color being arranged in the same row via the first sub-data line and a data voltage is applied to the remaining two sub-pixels among the five sub-pixels via the second sub-data line.

In addition, according to an embodiment of the present disclosure, there is provided a display device for driving a display panel by providing a data voltage to three or two sub-pixels emitting light of the same color being arranged in an odd-numbered row via one sub-data line, and providing a data voltage to two or three sub-pixels emitting light of the same color being arranged in an even-numbered row via another sub-data line.

In addition, according to an embodiment of the present disclosure, there is provided a display device in which the sub-pixels emitting light of the same color and respectively disposed in the first to fourth rows are arranged in a row direction in a staggered manner in a plan view of the display panel, wherein the driving circuits corresponding to the sub-pixels emitting light of the same color and respectively disposed in the first to fourth rows are arranged in a row direction in a staggered manner in the plan view.

According to an embodiment of the present disclosure, the display device may be realized in which each data line divides into a plurality of sub-data lines and a data voltage is applied to a predetermined multiple of sub-pixels emitting light of the same color via each of the divided sub-data lines, thereby reducing the number of data lines and thus reducing the cost of manufacturing the display panel.

In addition, in the display device according to another embodiment of the present disclosure, a plurality of sub-data lines are disposed such that a data voltage is applied to five sub-pixels emitting light of the same color being arranged in the same row via two sub-data lines, thereby minimizing an increase in the RC delay and thus securing charging characteristics.

In addition, the display device according to still another embodiment of the present disclosure applies the data voltage to three sub-pixels emitting light of the same color being arranged in the first row via the first sub-data line among the two sub-data lines, and applies the data voltage to two sub-pixels emitting light of the same color being arranged in the first row via the second sub-data line among the two sub-data lines, thereby reducing the number of drive ICs in the data driver and reducing the manufacturing cost of the display device.

In addition, the display device according to still yet another embodiment of the present disclosure applies the data voltage to two sub-pixels emitting light of the same color being arranged in the first row via the first sub-data line among the two sub-data lines, and applies the data voltage to three sub-pixels emitting light of the same color being arranged in the first row via the second sub-data line among the two sub-data lines, thereby reducing the number of data lines and the number of drive ICs in the data driver, and thus reducing the manufacturing cost of the display device.

In addition, according to still yet another embodiment of the present disclosure, when the data voltage is applied to three sub-pixels emitting light of the same color being arranged in the same row via the first sub-data line, the data voltage is applied to two sub-pixels emitting light of the same color being arranged in the same row via the second sub-data line. Alternatively, when the data voltage is applied to two sub-pixels emitting light of the same color being arranged in the same row via the first sub-data line, the data voltage is applied to three sub-pixels emitting light of the same color being arranged in the same row via the second sub-data line. Thus, a display device capable of column inversion may be realized.

In addition, in the display device according to still yet another embodiment of the present disclosure, when the data voltage is applied to three or two sub-pixels emitting light of the same color being arranged in the same row via the first sub-data line, the data voltage is applied to two or three sub-pixels emitting light of the same color being arranged in the same row via the second sub-data line, thereby reducing the number of drive ICs. Accordingly, the display device can operate at a low power level such that the power consumption can be reduced.

In addition, in the display device according to still yet another embodiment of the present disclosure, the five sub-pixels can operate using two sub-data lines, such that the number of data lines in the display panel may be reduced, and thus heat generation may be reduced, and the power consumed in the display device may be reduced.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF DRAWINGS

FIG. 1 is a schematic diagram of a display device according to an embodiment of the present disclosure.

FIG. 2 is a circuit diagram of a sub-pixel of a display device according to an embodiment of the present disclosure.

FIG. 3 is an example diagram illustrating a state in which a data line divides into sub-data lines in a display device according to an embodiment of the present disclosure.

FIG. 4 is an example diagram illustrating an arrangement relationship of sub-pixels of a display device according to an embodiment of the present disclosure.

FIG. 5 is a timing diagram of a gate voltage and a data voltage when a display device displays a monochromatic still screen according to an embodiment of the present disclosure.

FIG. 6 is a timing diagram of a gate voltage and a data voltage when a display device displays a vertical pattern screen according to an embodiment of the present disclosure.

FIG. 7 is an example diagram illustrating a connection relationship between sub-pixels emitting light of the same color, a gate line and sub-data lines in order to drive five pixels using two sub-data lines in a display device according to an embodiment of the present disclosure.

FIG. 8 is an example diagram illustrating an arrangement relationship of sub-pixels operating using two sub-data lines in a display device according to an embodiment of the present disclosure.

FIG. 9 is an example diagram illustrating a light emission state of a sub-pixel in a state in which a first gate voltage and a second gate voltage at a turn-on level are applied via a first gate line and a second gate line, respectively according to an embodiment of the present disclosure.

FIG. 10 is an example diagram illustrating a light emission state of a sub-pixel in a state in which a third gate voltage and a fourth gate voltage at a turn-on level are applied via a third gate line and a fourth gate line, respectively according to an embodiment of the present disclosure.

FIG. 11 is an example diagram illustrating a light emission state of a sub-pixel in a state in which a fifth gate voltage at a turn-on level is applied via a fifth gate line according to an embodiment of the present disclosure.

FIG. 12 is an example diagram illustrating an operation order of a pixel according to an embodiment of the present disclosure.

FIG. 13 is a timing diagram for a gate voltage and a data voltage when a display device displays a monochromatic still screen according to an embodiment of the present disclosure.

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify an entirety of the list of elements and may not modify the individual elements of the list.

In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other and may be technically associated with each other or operate with each other. The embodiments may be implemented independently of each other and may be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc. should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally. In a plan view of the display device, a column direction and a row direction intersecting each other are used to define an extension direction of a component, for example, a line.

Hereinafter, various embodiments of the present disclosure will be described in detail with reference to the accompanying drawings.

A transistor used in the display device of the present disclosure may be embodied as one or more transistors of an n-channel transistor NMOS and a p-channel transistor PMOS. The transistor may be embodied as an oxide semiconductor transistor having an oxide semiconductor layer as an active layer or a LTPS transistor having a low temperature poly-silicon (LTPS) layer as an active layer. The transistor may include at least a gate electrode, a source electrode, and a drain electrode. The transistor may be embodied as a thin-film transistor (TFT) on the display panel. The carriers in the transistor flow from the source electrode to the drain electrode. In the n-channel transistor NMOS, since the carriers are electrons, the source voltage is lower than the drain voltage so that electrons may flow from the source electrode to the drain electrode. In the n-channel transistor NMOS, the current flows from the drain electrode to the source electrode, and the source electrode may be an output terminal. In the p-channel transistor PMOS, since the carrier is a hole, the source voltage is higher than the drain voltage so that the hole may flow from the source electrode to the drain electrode. In the p-channel transistor PMOS, since holes flow from the source electrode to the drain electrode, a current flows from the source electrode to the drain electrode, and the drain electrode may be an output terminal. Therefore, it should be noted that the source and the drain of the transistor are not fixed because the source and the drain may be exchanged with each other based on the applied voltage. In the present disclosure, it is assumed that the transistor is an n-channel transistor (NMOS). However, embodiments of the present disclosure are not limited thereto, and the transistor may be embodied as an p-channel transistor, and accordingly, a circuit configuration may be changed.

A gate signal of a transistor used as each of switch elements swings between a gate-on voltage and a gate-off voltage. The gate-on voltage is set to a voltage higher than the threshold voltage Vth of the transistor, and the gate-off voltage is set to a voltage lower than the threshold voltage Vth of the transistor. The transistor is turned on in response to the gate-on voltage VGL, while being turned off in response to the gate-off voltage VGL. In the NMOS, the gate-on voltage may be the gate high voltage VGH, and the gate-off voltage may be the gate low voltage VGL. In the PMOS, the gate-on voltage may be the gate low voltage VGL, and the gate-off voltage may be the gate high voltage VGH.

Hereinafter, various embodiments of the present disclosure will be described in detail with reference to the accompanying drawings.

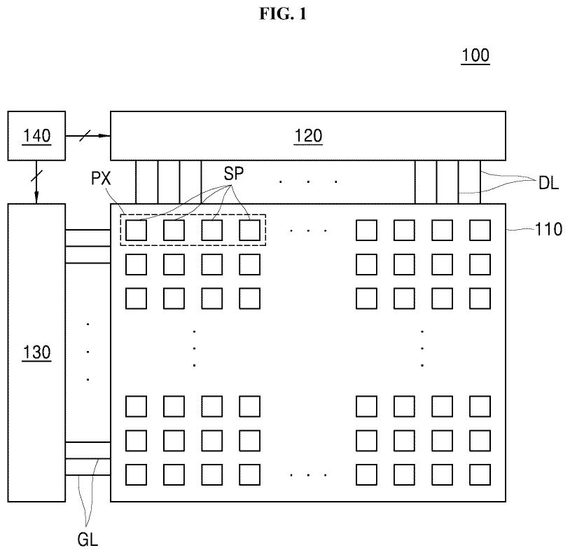

FIG. 1 is a schematic diagram of a display device according to an embodiment of the present disclosure.

Referring to FIG. 1, a display device 100 according to an embodiment of the present disclosure may include a display panel 110, a data driver 120, a gate driver 130, and a timing controller 140.

The configuration of the display panel 110 illustrated in FIG. 1 is merely according to an embodiment, and the components of the display panel 110 are not limited to those in the embodiment as illustrated in FIG. 1, and some components may be added, changed, or deleted as necessary.

According to an embodiment, the display panel 110 is a panel for displaying an image. The display panel 110 may include various circuits, lines, and light-emitting elements disposed on a substrate. An area of the display panel 110 may divide into pixels areas defined by a plurality of data lines DL and a plurality of gate lines GL intersecting each other, and may include a plurality of pixels PX respectively disposed in the pixel areas and connected to the plurality of data lines DL and the plurality of gate lines GL.

The display panel 110 may include a display area including the plurality of pixels PX and a non-display area in which various signal lines or pads are formed.

The display panel 110 may be embodied as a display panel 110 used in various display devices such as a liquid crystal display device, an organic light-emitting display device, an electrophoretic display device, and the like.

Hereinafter, an example is described in which the display panel 110 is a panel used in an organic light-emitting display device. However, embodiments of the present disclosure are not limited thereto.

According to an embodiment, the timing controller 140 may receive a timing signal such as a vertical synchronization signal, a horizontal synchronization signal, a data enable signal, and a dot clock via a receiving circuit such as an LVDS or TMDS interface connected to a host system. The timing controller 140 may generate timing control signals for controlling the data driver 120 and the gate driver 130 based on the input timing signal.

According to an embodiment, the data driver 120 may supply a data voltage DATA to the plurality of sub-pixels SP. The data driver 120 may include a plurality of source drive integrated circuits (IC). The plurality of source drive IC may receive digital video data and a source timing control signal from the timing controller 140.

The plurality of source drive ICs may convert the digital video data into a gamma voltage in response to the source timing control signal to generate the data voltage DATA and may supply the data voltage DATA via the data line DL of the display panel 110. The plurality of source drive ICs may be connected to the data line DL of the display panel 110 in a chip on glass (COG) process or a tape automated bonding (TAB) process.

In addition, the source drive ICs may be formed on the display panel 110 or may be formed on a separate PCB substrate which may be connected to the display panel 110.

According to an embodiment, the gate driver 130 may supply a gate signal to the plurality of sub-pixels SP. The gate driver 130 may include a level shifter and a shift register. The level shifter may shift a level of a clock signal input from the timing controller 140 to a transistor-transistor-logic (TTL) level and then supply the signal having the shifted level to the shift register. The shift register may be formed in the non-display area of the display panel 110 in an GIP (gate in panel) manner. However, embodiments of the present disclosure are not limited thereto.

The shift register may include a plurality of stages that shift and output the gate signal in response to the clock signal and a driving signal. The plurality of stages included in the shift register may sequentially output the gate signal via a plurality of output terminals.

According to an embodiment, the display panel 110 may include a plurality of sub-pixels SP. The plurality of sub-pixels SP may be sub-pixels SP for emitting light of different colors. For example, the plurality of sub-pixels SP may include a red sub-pixel, a green sub-pixel, a blue sub-pixel, and a white sub-pixel. However, embodiments of the present disclosure are not limited thereto. The plurality of sub-pixels SP may constitute the pixel PX.

That is, the red sub pixel, the green sub pixel, the blue sub pixel, and the white sub pixel may constitute a single pixel PX, and the display panel 110 may include a plurality of pixels PX.

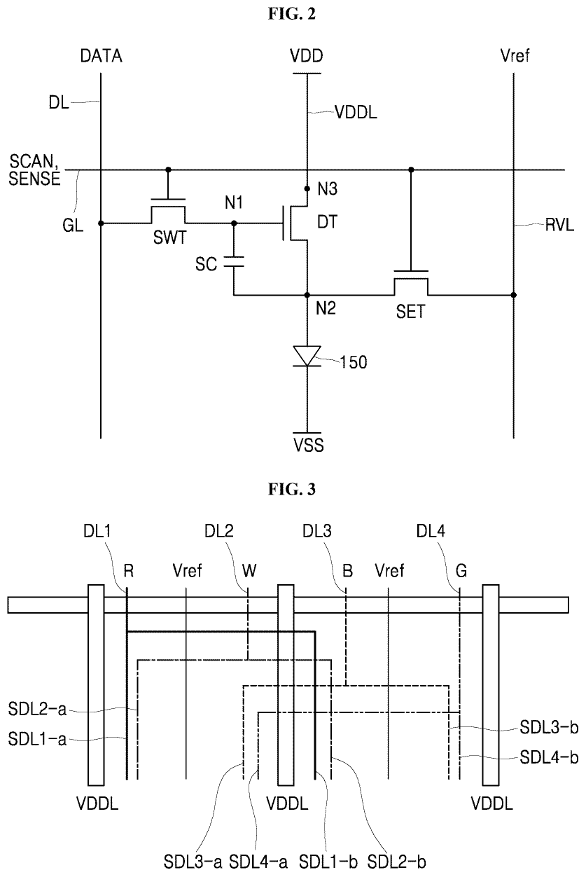

Hereinafter, for a more detailed description of a driving circuit for driving one sub-pixel SP, FIG. 2 will be referred to together with FIG. 1.

FIG. 2 is a circuit diagram of a sub-pixel of a display device according to an embodiment of the present disclosure.

FIG. 2 illustrates a circuit diagram of one sub-pixel SP among the plurality of sub-pixels SP of the display device 100.

Referring to FIG. 2, the sub-pixel SP may include a switching transistor SWT, a sensing transistor SET, a driving transistor DT, a storage capacitor SC, and a light-emitting element 150.

According to an embodiment, the light-emitting element 150 may include an anode, an organic layer stack, and a cathode. The organic layer stack may include a stack of various organic layers such as a hole injection layer, a hole transport layer, an organic light-emitting layer, an electron transport layer, and an electron injection layer. The anode of the light-emitting element 150 may be connected to an output terminal of the driving transistor DT, and a low potential voltage VSS may be applied to the cathode of the light-emitting element 150.

Although FIG. 2 illustrates that the light-emitting element 150 is embodied as the organic light-emitting element 150, the present disclosure is not limited thereto, and an inorganic light-emitting diode, that is, LED, may also be used as the light-emitting element 150.

Referring to FIG. 2, the switching transistor SWT is a transistor for transferring the data voltage DATA to a first node N1 connected to a gate electrode of the driving transistor DT. The switching transistor SWT may include a drain electrode connected to the data line DL, a gate electrode connected to the gate line GL, and a source electrode connected to the gate electrode of the driving transistor DT. The switching transistor SWT may be turned on based on a gate voltage GATE applied from the gate line GL to transmit the data voltage DATA supplied from the data line DL to the first node N1 connected to the gate electrode of the driving transistor DT.

Referring to FIG. 2, the driving transistor DT is a transistor for driving the light-emitting element 150 by supplying a driving current to the light-emitting element 150. The driving transistor DT may include a gate electrode connected to the first node N1, a source electrode connected to a second node N2 and corresponding to an output terminal, and a drain electrode connected to a third node N3 and corresponding to an input terminal.

The gate electrode of the driving transistor DT may be connected to the switching transistor SWT, a drain electrode thereof may receive a high potential voltage VDD via a high potential voltage line VDDL, and a source electrode thereof may be connected to the anode of the light-emitting element 150.

Referring to FIG. 2, the storage capacitor SC is a capacitor for maintaining a voltage corresponding to the data voltage DATA for one frame. One electrode of the storage capacitor SC may be connected to the first node N1, and the other electrode thereof may be connected to the second node N2.

In one example, in the display device 100, as an operation time of each sub-pixel SP increases, degradation of a circuit element such as the driving transistor DT may proceed. Accordingly, an intrinsic characteristic value of the circuit element such as the driving transistor DT may be changed.

In this regard, the intrinsic characteristic value of the circuit element may include the threshold voltage Vth of the driving transistor DT, the mobility α of the driving transistor DT, etc. The change in the intrinsic characteristic value of the circuit element may cause a change in luminance of the corresponding sub-pixel SP.

Therefore, the change in the intrinsic characteristic value of the circuit element may be used as the same concept as the change in the luminance of the sub-pixel SP.

In addition, the change amount in the intrinsic characteristic value of the circuit element of each sub-pixel SP may vary depending on the deterioration amount of each circuit element. Thus, the change amounts in the intrinsic characteristic value of the circuit elements of different sub-pixels SP having the different deterioration amounts of the circuit elements thereof may be different from each other. Such a difference between the change amounts in the intrinsic characteristic value of the respective circuit elements of the sub-pixels may cause a luminance deviation between luminance of the sub-pixels SP.

Therefore, the deviation between the intrinsic characteristic value of the circuit elements of the different sub-pixels SP may be used as the same concept as the luminance deviation between the luminance of the different sub-pixels SP.

The change in the intrinsic characteristic value of the circuit element, that is, the change in the luminance of the sub-pixel SP and the deviations between in the intrinsic characteristic values of the circuit elements of the sub-pixels, that is, the deviation between the luminance of the sub-pixels SP, may cause problems such as a decrease in accuracy of the luminance realized in the sub-pixel SP or a screen abnormality.

Accordingly, in the sub-pixel SP of the display device 100 according to an embodiment of the present disclosure, a sensing function of sensing the intrinsic characteristic value of the sub-pixel SP and a compensation function of compensating for the intrinsic characteristic value of the sub-pixel SP based on the sensing result may be provided.

Accordingly, as shown in FIG. 2, the sub-pixel SP may further include a sensing transistor SET for effectively controlling the voltage state of the source electrode of the driving transistor DT in addition to the switching transistor SWT, the driving transistor DT, the storage capacitor SC, and the light-emitting element 150.

Referring to FIG. 2, the sensing transistor SET is connected to and disposed between the source electrode of the driving transistor DT and a reference voltage line RVL that supplies a reference voltage Vref. A gate electrode of the sensing transistor SET is connected to the gate line GL. Accordingly, the sensing transistor SET may be turned on based on the sensing signal SENSE applied via the gate line GL to apply the reference voltage Vref supplied via the reference voltage line RVL to the source electrode of the driving transistor DT. In addition, the sensing transistor SET may be used as one of voltage sensing paths for the source electrode of the driving transistor DT.

Referring to FIG. 2, the switching transistor SWT and the sensing transistor SET of the sub-pixel SP may share one gate line GL. That is, the switching transistor SWT and the sensing transistor SET may be connected to the same gate line GL and may receive the same gate signal therefrom. However, for convenience of description, a voltage applied to the gate electrode of the switching transistor SWT is referred to as the gate voltage GATE, and a voltage applied to the gate electrode of the sensing transistor SET is referred to as a sensing signal SENSE. However, the gate voltage GATE and the sensing signal SENSE applied to one sub-pixel SP are the same signal transmitted via the same gate line GL.

However, the present disclosure is not limited thereto, and only the switching transistor SWT may be connected to the gate line GL, and the sensing transistor SET may be connected to a separate sensing line. Accordingly, the gate voltage GATE may be applied to the switching transistor SWT via the gate line GL, and the sensing signal SENSE may be applied to the sensing transistor SET via the sensing line.

Accordingly, the reference voltage Vref is applied to the source electrode of the driving transistor DT via the sensing transistor SET. In addition, a voltage for sensing the threshold voltage Vth of the driving transistor DT or the mobility α of the driving transistor DT is detected via the reference voltage line RVL. In addition, the data driver 120 may compensate for the data voltage DATA based on an amount of change in the detected threshold voltage Vth of the driving transistor DT or the detected mobility α of the driving transistor DT.

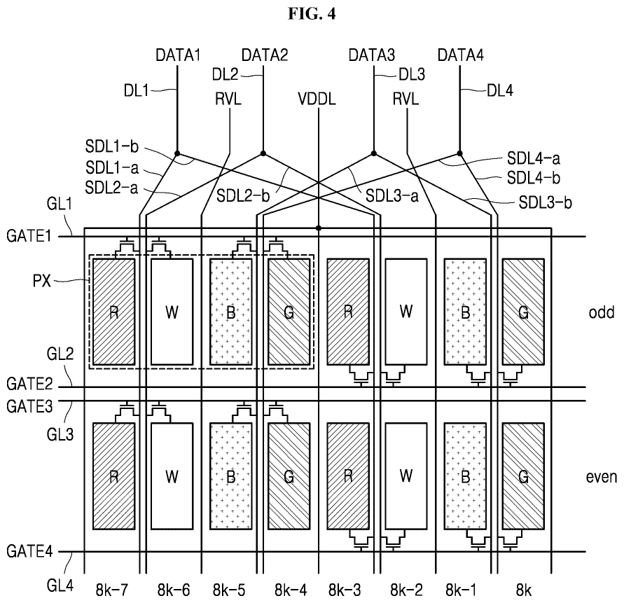

Hereinafter, FIGS. 3 and 4 are referred together to describe an arrangement relationship of a plurality of sub-pixels.

FIG. 3 is an example diagram illustrating a state in which a data line divides into sub-data lines in a display device according to an embodiment of the present disclosure. FIG. 4 is an example diagram illustrating an arrangement relationship of sub-pixels of a display device according to an embodiment of the present disclosure.

For convenience of description, only four pixels PX arranged in a 2×2 matrix form are illustrated in FIGS. 3 and 4. An arrangement relationship of four pixels PX arranged in a 2×2 matrix form may be repeated in the display area DA. In addition, a transistor disposed between the sub-pixels R, G, B, and W and the data line means the switching transistor SWT described in FIG. 2.

According to an embodiment, each of the plurality of data lines DL1, DL2, DL3, and DL4 may divide into a plurality of sub-data lines SDL1-a and SDL1-b, SDL2-a and SDL2-b, SDL3-a and SDL3-b, or SDL4-a and SDL4-b.

Specifically, the first data line DL1 may divide into a plurality of first sub-data lines SDL1-a and SDL1-b, and the second data line DL2 may divide into a plurality of second sub-data lines SDL2-a and SDL2-b.

The third data line DL3 may divide into the plurality of third sub-data lines SDL3-a and SDL3-b, and the fourth data line DL4 may divide into the plurality of fourth sub-data lines SDL4-a and SDL4-b.

According to an embodiment, the first sub-data lines SDL1-a and SDL1-b may include a (1-a)th sub-data line SDL1-a and a (1-b)th sub-data line SDL1-b, and the second sub-data lines SDL2-a and SDL2-b may include a (2-a)th sub-data line SDL2-a and a (2-b)th sub-data line SDL2-b.

The third sub-data lines SDL3-a and SDL3-b may include a (3-a)th sub-data line SDL3-a and a (3-b)th sub-data line SDL3-b, and the fourth sub-data lines SDL4-a and SDL4-b may include a (4-a)th sub-data line SDL4-a and a (4-b)th sub-data line SDL4-b.

Each of the plurality of high potential voltage lines VDDL may be disposed between adjacent ones of the plurality of pixels PX.

According to an embodiment, one pixel PX may include four sub-pixels R, G, B, and W. For example, as shown in FIG. 4, the pixel PX may include a first sub-pixel R, a second sub-pixel W, a third sub-pixel B, and a fourth sub-pixel G. For example, the first sub-pixel R may be a red sub-pixel, the second sub-pixel W may be a white sub-pixel, the third sub-pixel B may be a blue sub-pixel, and the fourth sub-pixel G may be a green sub-pixel. However, the present disclosure is not limited thereto, and the plurality of sub-pixels may include sub-pixels emitting light of various colors magenta, yellow, and cyan.

In addition, the plurality of sub-pixels emitting light of the same color may be arranged in the same column. That is, the plurality of first sub-pixels R may be arranged in the same column, the plurality of second sub-pixels W may be arranged in the same column, the plurality of third sub-pixels B may be arranged in the same column, and the plurality of fourth sub-pixels G may be arranged in the same column.

More specifically, as illustrated in FIG. 4, the plurality of first sub-pixels R may be arranged in a (8k-7)th column and a (8k-3)th column, and the plurality of second sub-pixels W may be arranged in a (8k-6)th column and a (8k-2)th column. In addition, the plurality of third sub-pixels B may be arranged in a (8k-5)th column and a (8k-1)th column, and the plurality of fourth sub-pixels G may be arranged in a (8k-4)th column and an 8k-th column. However, k means a natural number greater than or equal to 1.

That is, the first sub-pixel R, the second sub-pixel W, the third sub-pixel B, and the fourth sub-pixel G may be sequentially and repeatedly arranged along one odd row or one even row even.

According to an embodiment, each of the plurality of first sub-data lines SDL1-a and SDL1-b may be disposed adjacent to the plurality of first sub-pixels R and be respectively connected to the plurality of first sub-pixels R.

Specifically, the (1-a)th sub-data line SDL1-a may be disposed between the plurality of first sub-pixels R arranged in a (8k-7)th column and the plurality of second sub-pixels W arranged in a (8k-6)th column, and may be electrically connected to the plurality of first sub-pixels R arranged in the (8k-7)th column. In addition, the (1-b)th sub-data line SDL1-b may be disposed between the plurality of first sub-pixels R arranged in a (8k-3)th column and the plurality of second sub-pixels W arranged in a (8k-2)th column, and may be electrically connected to the plurality of first sub-pixels R arranged in the (8k-3)th column.

According to an embodiment, each of the plurality of second sub-data lines SDL2-a and SDL2-b may be disposed adjacent to the plurality of second sub-pixels W and may be connected to the plurality of second sub-pixels W.

Specifically, the (2-a)th sub-data line SDL2-a may be disposed between the plurality of first sub-pixels R arranged in a (8k-7)th column and the plurality of second sub-pixels W arranged in a (8k-6)th column, and may be electrically connected to the plurality of second sub-pixels W arranged in the (8k-6)th column. In addition, the (2-b)th sub-data line SDL2-b may be disposed between the plurality of first sub-pixels R arranged in a (8k-3)th column and the plurality of second sub-pixels W arranged in a (8k-2)th column and be electrically connected to the plurality of second sub-pixels W arranged in the (8k-2)th column.

According to an embodiment, each of the plurality of third sub-data lines SDL3-a and SDL3-b may be disposed adjacent to the plurality of third sub-pixels B and may be connected to the plurality of third sub-pixels B.

Specifically, the (3-a)th sub-data line SDL3-a may be disposed between the plurality of third sub-pixels B arranged in a (8k-5)th column and the plurality of fourth sub-pixels G arranged in a (8k-4)th column and may be electrically connected to the plurality of third sub-pixels B arranged in the (8k-5)th column. In addition, the (3-b)th sub-data line SDL3-b may be disposed between the plurality of third sub-pixels B arranged in a (8k-1)th column and the plurality of fourth sub-pixels G arranged in a 8k-th column and may be electrically connected to the plurality of third sub-pixels B arranged in the (8k-1)th column.

According to an embodiment, each of the plurality of fourth sub-data lines SDL4-a and SDL4-W may be disposed adjacent to the plurality of fourth sub-pixels G and may be connected to the plurality of fourth sub-pixels G.

Specifically, the (4-a)th sub-data line SDL4-a may be disposed between the plurality of third sub-pixels B arranged in a (8k-5)th column and the plurality of fourth sub-pixels G arranged in a (8k-4)th column and may be electrically connected to the plurality of fourth sub-pixels G arranged in the (8k-4)th column. The (4-b)th sub-data lines SDL4-b may be disposed between the plurality of third sub-pixels B arranged in a (8k-1)th column and the plurality of fourth sub-pixels G arranged in an 8k-th column and may be electrically connected to the plurality of fourth sub-pixels G arranged in the 8k-th column.

According to an embodiment, a first data voltage DATA1 as a red data voltage may be applied to the first data line DL1, and a second data voltage DATA2 as a white data voltage may be applied to the second data line DL2. In addition, a third data voltage DATA3 as a blue data voltage may be applied to the third data line DL3, and a fourth data voltage DATA4 as a green data voltage may be applied to the fourth data line DL4.

Accordingly, the first data voltage DATA1 as a red data voltage may also be applied to the plurality of first sub-data lines SDL1-a and SDL1-b, and the second data voltage DATA2 as a white data voltage may also be applied to the plurality of second sub-data lines SDL2-a and SDL2-b. In addition, the third data voltage DATA3 as a blue data voltage may also be applied to the plurality of third sub-data lines SDL3-a and SDL3-b, and the fourth data voltage DATA4 as a green data voltage may also be applied to the plurality of fourth sub-data lines SDL4-a and SDL4-b.

According to an embodiment, each of the plurality of gate lines GL1 to GL4 may be disposed on each of both opposing sides in the column direction of a row of the plurality of sub-pixels R, G, B, and W. Two gate lines GL2 and GL3 may be disposed between adjacent rows of the plurality of sub-pixels R, G, B, and W.

Specifically, referring to FIG. 4, the first gate line GL1 and the second gate line GL2 may be respectively disposed on both opposing sides in the column direction of the plurality of sub-pixels R, G, B, and W of the odd-numbered row, while the third gate line GL3 and the fourth gate line GL4 may be respectively disposed on both opposing sides in the column direction of the plurality of sub-pixels R, G, B, and W of the even-numbered row. Accordingly, the second gate line GL2 and the third gate line GL3 may be disposed between the plurality of sub-pixels R, G, B, and W arranged in the odd-numbered row and the plurality of sub-pixels R, G, B, and W arranged in the even-numbered row even.

Each of the plurality of pixels PX may be connected to the same gate line GL1 to GL4, and adjacent pixels PX among the plurality of pixels PX may be connected to different gate lines GL1 to GL4.

Specifically, referring to FIG. 4, the sub-pixels R, W, B, and G arranged in a (8k-7)th column to the (8k-4)th column of the odd-numbered row odd may be connected to the first gate line GL1, and the sub-pixels R, W, B, and G arranged in a (8k-3)th column to the 8k-th column of the odd-numbered row odd may be connected to the second gate line GL2. In addition, the sub-pixels R, W, B, and G arranged in a (8k-7)th column to the (8k-4)th column of the even-numbered row even may be connected to the third gate line GL3, and the sub-pixels R, W, B, and G arranged in a (8k-3)th column to the 8k-th column of the even-numbered row even may be connected to the fourth gate line GL4.

Each of the plurality of reference voltage lines RVL may be disposed inside one pixel PX, and each of the plurality of high potential voltage lines VDDL may be disposed between adjacent ones of the plurality of pixels PX.

Specifically, one of the plurality of reference voltage lines RVL may be disposed between the plurality of second sub-pixels W arranged in a (8k-6)th column and the plurality of third sub-pixels B arranged in a (8k-5)th column, and another thereof may be disposed between the plurality of second sub-pixels W arranged in a (8k-2)th column and the plurality of third sub-pixels B arranged in a (8k-1)th column.

One of the plurality of high potential voltage lines VDDL may be disposed between the plurality of fourth sub-pixels G arranged in a (8k-4)th column and the plurality of first sub-pixels R arranged in a (8k-3)th column, and another thereof may be disposed outside and on a left side of the plurality of first sub-pixels R arranged in a (8k-7)th column, and still another thereof may be disposed outside and on a right side of the plurality of fourth sub-pixels G arranged in a 8k-th column.

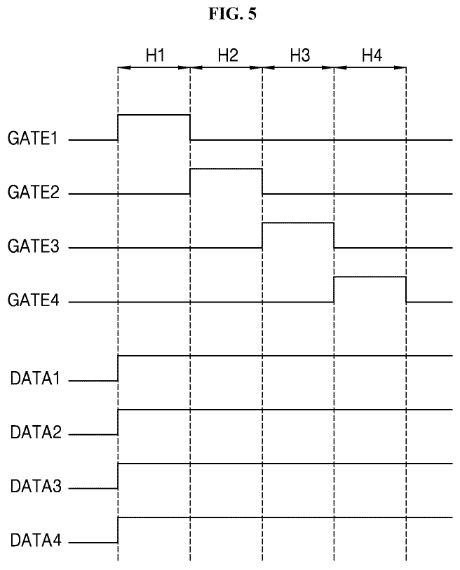

Hereinafter, a method of driving a monochromatic still screen and a method of driving a vertical pattern screen of the display device 100 according to an embodiment of the present disclosure will be described with reference to FIGS. 4 and 5.

FIG. 5 is a timing diagram of a gate voltage and a data voltage when a display device according to an embodiment of the present disclosure displays a monochromatic still screen.

As shown in FIGS. 4 and 5, the first gate voltage GATE1 is output via the first gate line GL1, the second gate voltage GATE2 is output via the second gate line GL2, the third gate voltage GATE3 is output via the third gate line GL3, and the fourth gate voltage GATE4 is output via the fourth gate line GL4.

In addition, the first data voltage DATA1 is output via the first data line DL1, the second data voltage DATA2 is output via the second data line DL2, the third data voltage DATA3 is output via the third data line DL3, and the fourth data voltage DATA4 is output via the fourth data line DL4.

As illustrated in FIG. 5, during a first horizontal period H1, the first gate voltage GATE1 is the gate high voltage, and the second gate voltage GATE2, the third gate voltage GATE3, and the fourth gate voltage GATE4 are the gate low voltages. In addition, during the first horizontal period H1, each of the first data voltage DATA1 to the fourth data voltage DATA4 may be a data voltage of a predetermined level for implementing a predetermined grayscale.

Accordingly, during the first horizontal period H1, all of the switching transistors respectively connected to the plurality of first sub-pixels R arranged in a (8k-7)th column, the plurality of second sub-pixels W arranged in a (8k-6)th column, the plurality of third sub-pixels B arranged in a (8k-5)th column, and the plurality of fourth sub-pixels G arranged in a (8k-4)th column are turned on.

Accordingly, during the first horizontal period H1, in the odd-numbered row odd, the first data voltage DATA1 may be charged into the plurality of first sub-pixels R arranged in a (8k-7)th column, the second data voltage DATA2 may be charged into the plurality of second sub-pixels W arranged in a (8k-6)th column, the third data voltage DATA3 may be charged into the plurality of third sub-pixels B arranged in a (8k-5)th column, and the fourth data voltage DATA4 may be charged into the plurality of fourth sub-pixels G arranged in a (8k-4)th column.

As illustrated in FIG. 5, during a second horizontal period H2, the second gate voltage GATE2 is the gate high voltage, and the first gate voltage GATE1, the third gate voltage GATE3, and the fourth gate voltage GATE4 are the gate low voltages. In addition, even during the second horizontal period H2, each of the first data voltage DATA1 to the fourth data voltage DATA4 may be a data voltage of a predetermined level for implementing a predetermined gray level.

Accordingly, during the second horizontal period H2, all of the switching transistors respectively connected to the plurality of first sub-pixels R arranged in a (8k-3)th column, the plurality of second sub-pixels W arranged in a (8k-2)th column, the plurality of third sub-pixels B arranged in a (8k-1)th column, and the plurality of fourth sub-pixels G arranged in a 8k-th column in the odd-numbered row are turned on.

Accordingly, during the second horizontal period H2, in the odd-numbered row odd, the first data voltage DATA1 may be charged into the plurality of first sub-pixels R arranged in a (8k-3)th column, the second data voltage DATA2 may be charged into the plurality of second sub-pixels W arranged in a (8k-2)th column, the third data voltage DATA3 may be charged into the plurality of third sub-pixels B arranged in a (8k-1)th column, and the fourth data voltage DATA4 may be charged into the plurality of fourth sub-pixels G arranged in a 8k-th column.

As illustrated in FIG. 5, during a third horizontal period H3, the third gate voltage GATE3 is the gate high voltage, and the first gate voltage GATE1, the second gate voltage GATE2, and the fourth gate voltage GATE4 are the gate low voltages. In addition, even during the third horizontal period H3, each of the first data voltage DATA1 to the fourth data voltage DATA4 may be a data voltage of a predetermined level for implementing a predetermined grayscale.

Accordingly, during the third horizontal period H3, all of the switching transistors respectively connected to the plurality of first sub-pixels R arranged in a (8k-7)th column, the plurality of second sub-pixels W arranged in a (8k-6)th column, the plurality of third sub-pixels B arranged in a (8k-5)th column, and the plurality of fourth sub-pixels G arranged in a (8k-4)th column in the even-numbered row even are turned on.

Accordingly, during the third horizontal period H3, in the even-numbered row even, the first data voltage DATA1 may be charged into the plurality of first sub-pixels R arranged in a (8k-7)th column, the second data voltage DATA2 may be charged into the plurality of second sub-pixels W arranged in a (8k-6)th column, the third data voltage DATA3 may be charged into the plurality of third sub-pixels B arranged in a (8k-5)th column, and the fourth data voltage DATA4 may be charged into the plurality of fourth sub-pixels G arranged in a (8k-4)th column.

As illustrated in FIG. 5, during a fourth horizontal period H4, the fourth gate voltage GATE4 is the gate high voltage, and the first gate voltage GATE1, the second gate voltage GATE2, and the third gate voltage GATE3 are the gate low voltages. In addition, even during the third horizontal period H3, each of the first data voltage DATA1 to the fourth data voltage DATA4 may be a data voltage of a predetermined level for implementing a predetermined grayscale.

Accordingly, during the fourth horizontal period H4, all of the switching transistors respectively connected to the plurality of first sub-pixels R arranged in a (8k-3)th column, the plurality of second sub-pixels W arranged in a (8k-2)th column, the plurality of third sub-pixels B arranged in a (8k-1)th column, and the plurality of fourth sub-pixels G arranged in a 8k-th column in the even-numbered row even are turned on.

Accordingly, during the fourth horizontal period H4, in the even-numbered row even, the first data voltage DATA1 may be charged into the plurality of first sub-pixels R arranged in a (8k-3)th column, the second data voltage DATA2 may be charged into the plurality of second sub-pixels W arranged in a (8k-2)th column, the third data voltage DATA3 may be charged into the plurality of third sub-pixels B arranged in a (8k-1)th column, and the fourth data voltage DATA4 may be charged into the plurality of fourth sub-pixels G arranged in a 8k-th column.

As described above, when the display device 100 according to an embodiment of the present disclosure displays the monochromatic still screen, each of the first to fourth data voltages DATA1 to DATA4 may have the same level during the first to fourth horizontal periods H1 to H4, that is, during one frame. Accordingly, each of the first to fourth data voltages DATA1 to DATA4 is maintained at a constant data voltage level during one frame.

The display device operates in a double rate driving (DRD) manner using the data line division into the sub-data lines at a lower end of a link for the DRD application. The DRD scheme shares two sub-data lines, thereby increasing the RC delay.

In order to solve this problem, the present disclosure provides a display device in which five sub-pixels operate via two sub-data lines such that the number of sub-data lines is reduced and the data voltage is shared by the sub-data lines.

To this end, the display device according to an embodiment of the present disclosure may drive two or three sub-pixels via the first sub-data line and drive three or two sub-pixels via the second sub-data line. In addition, the five sub-pixels may be arranged in a flip structure with respect to each other.

Accordingly, in the display device according to an embodiment of the present disclosure, a sub-data line is not required for one of the five pixels, and the five sub-pixels may operate based on the 2.5RD as a median between the DRD and the TRD.

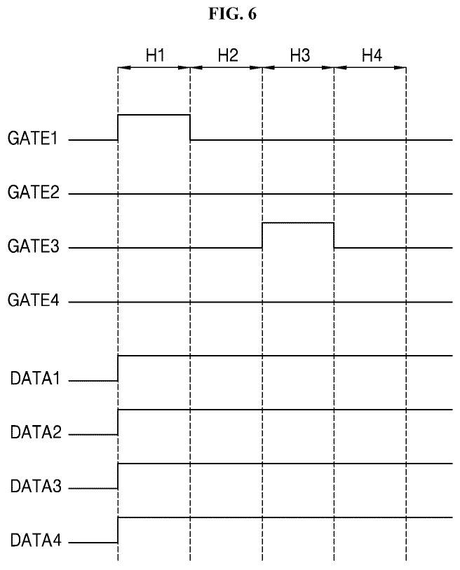

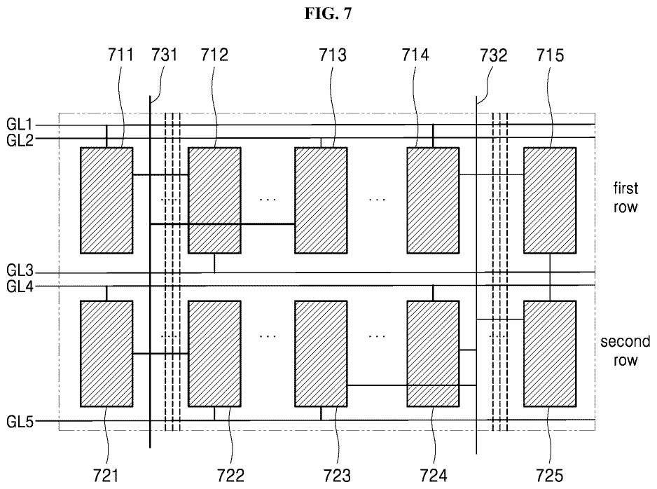

FIG. 6 is a timing diagram for a gate voltage and a data voltage when a display device according to an embodiment of the present disclosure displays a vertical pattern screen.

As illustrated in FIG. 6, during the first horizontal period H1, the first gate voltage GATE1 is a gate high voltage, and the second gate voltage GATE2, the third gate voltage GATE3, and the fourth gate voltage GATE4 are gate low voltages. In addition, during the first horizontal period H1, each of the first data voltage DATA1 to the fourth data voltage DATA4 may be a data voltage of a predetermined level for implementing a predetermined grayscale.

Accordingly, during the first horizontal period H1, all of the switching transistors respectively connected to the plurality of first sub-pixels R arranged in a (8k-7)th column, the plurality of second sub-pixels W arranged in a (8k-6)th column, the plurality of third sub-pixels B arranged in a (8k-5)th column, and the plurality of fourth sub-pixels G arranged in a (8k-4)th column in the odd-numbered row odd are turned on.

Accordingly, during the first horizontal period H1, in the odd-numbered row odd, the first data voltage DATA1 may be charged into the plurality of first sub-pixels R arranged in a (8k-7)th column, the second data voltage DATA2 may be charged into the plurality of second sub-pixels W arranged in a (8k-6)th column, the third data voltage DATA3 may be charged into the plurality of third sub-pixels B arranged in a (8k-5)th column, and the fourth data voltage DATA4 may be charged into the plurality of fourth sub-pixels G arranged in a (8k-4)th column.

As illustrated in FIG. 6, during the second horizontal period H2, all of the first gate voltage GATE1, the second gate voltage GATE2, the third gate voltage GATE3, and the fourth gate voltage GATE4 are gate low voltages. In addition, even during the second horizontal period H2, each of the first data voltage DATA1 to the fourth data voltage DATA4 may be a data voltage of a predetermined level for implementing a predetermined gray level.

Accordingly, during the second horizontal period H2, all of the switching transistors respectively connected to all sub-pixels are turned off. Accordingly, during the second horizontal period H2, in the odd-numbered row odd, the first data voltage DATA1 is not charged into the plurality of first sub-pixels R arranged in a (8k-3)th column, the second data voltage DATA2 is not charged into the plurality of second sub-pixels W arranged in a (8k-2)th column, the third data voltage DATA3 is not charged into the plurality of third sub-pixels B arranged in a (8k-1)th column, and the fourth data voltage DATA4 is not charged into the plurality of fourth sub-pixels G arranged in a 8k-th column.

As illustrated in FIG. 6, during the third horizontal period H3, the third gate voltage GATE3 is the gate high voltage, and the first gate voltage GATE1, the second gate voltage GATE2, and the fourth gate voltage GATE4 are the gate low voltages. In addition, even during the third horizontal period H3, each of the first data voltage DATA1 to the fourth data voltage DATA4 may be a data voltage of a predetermined level for implementing a predetermined grayscale.

Accordingly, during the third horizontal period H3, all of the switching transistors respectively connected to the plurality of first sub-pixels R arranged in a (8k-7)th column, the plurality of second sub-pixels W arranged in a (8k-6)th column, the plurality of third sub-pixels B arranged in a (8k-5)th column, and the plurality of fourth sub-pixels G arranged in a (8k-4)th column in the even-numbered row even are turned on.

Accordingly, during the third horizontal period H3, in the even-numbered row even, the first data voltage DATA1 may be charged into the plurality of first sub-pixels R arranged in a (8k-7)th column, the second data voltage DATA2 may be charged into the plurality of second sub-pixels W arranged in a (8k-6)th column, the third data voltage DATA3 may be charged into the plurality of third sub-pixels B arranged in a (8k-5)th column, and the fourth data voltage DATA4 may be charged into the plurality of fourth sub-pixels G arranged in a (8k-4)th column.

As illustrated in FIG. 6, during the fourth horizontal period H4, all of the first gate voltage GATE1, the second gate voltage GATE2, the third gate voltage GATE3, and the fourth gate voltage GATE4 are gate low voltages. In addition, even during the fourth horizontal period H4, each of the first data voltage DATA1 to the fourth data voltage DATA4 may be a data voltage of a predetermined level for implementing a predetermined grayscale.

Accordingly, during the fourth horizontal period H4, all switching transistors connected to all sub-pixels SP are turned off. Accordingly, during the fourth horizontal period H4, in the even-numbered row even, the first data voltage DATA1 may not be charged into the plurality of first sub-pixels R arranged in a (8k-3)th column, the second data voltage DATA2 may not be charged into the plurality of second sub-pixels W arranged in a (8k-2)th column, the third data voltage DATA3 may not be charged into the plurality of third sub-pixels B arranged in a (8k-1)th column, and the fourth data voltage DATA4 may not be charged into the plurality of fourth sub-pixels G arranged in a 8k-th column.

As described above, when the display device 100 according to an embodiment of the present disclosure displays the vertical pattern screen, each of the first data voltage DATA1 to the fourth data voltage DATA4 may be at the same level during the first to fourth horizontal periods H 4, that is, during one frame. Accordingly, each of the first data voltage DATA1 to the fourth data voltage DATA4 is maintained at a constant data voltage during one frame.

In a conventional display device, two sub-pixels emitting light of different colors are connected to one data line. Accordingly, in the conventional display device, the data voltage applied to the data line should be a data voltage corresponding to a plurality of colors, change in the data voltage (data transition) is essential. That is, data voltage change (data transition) may occur even within one horizontal period, and data voltage change (data transition) should occur within at least one frame.

Accordingly, when the data voltage change (data transition) frequently occurs, the data voltage is not completely charged during one horizontal period. Furthermore, when the data voltage change (data transition) frequently occurs, the heat generation from the data driver supplying the data voltage is increased.

On the other hand, in the display device according to an embodiment of the present disclosure, each of the plurality of data lines DL1, DL2, DL3, and DL4 may divide into the plurality of sub-data lines SDL1-a and SDL1-b, SDL2-a and SDL2-b, SDL3-a and SDL3-b, or SDL4-a and SDL4-b. The plurality of sub-data lines SDL1-a and SDL1-b, SDL2-a and SDL2-b, SDL3-a and SDL3-b, or SDL4-a and SDL4-b may be connected to the sub-pixels R, G, B, or W emitting light of the same color. Accordingly, in the display device according to an embodiment of the present disclosure, the plurality of data lines only need to output the data voltage corresponding to one color. Thus, when a single-color still screen or a vertical pattern screen is implemented, the data voltage change (data transition) does not occur during one frame.

Accordingly, the data voltage may be completely charged during one frame, thereby solving the problem of incomplete charging of the data voltage in the conventional display device. In addition, since the data voltage is kept constant during one frame, the heat generation phenomenon form the data driver supplying the data voltage may also be reduced.

Moreover, even when the display device displays the vertical pattern screen, the data voltage change (data transition) does not occur during one frame, so that the burden of the data driver may be minimized when the pattern vertical pattern screen is implemented.

Hereinafter, a display device according to another embodiment of the present disclosure will be described.

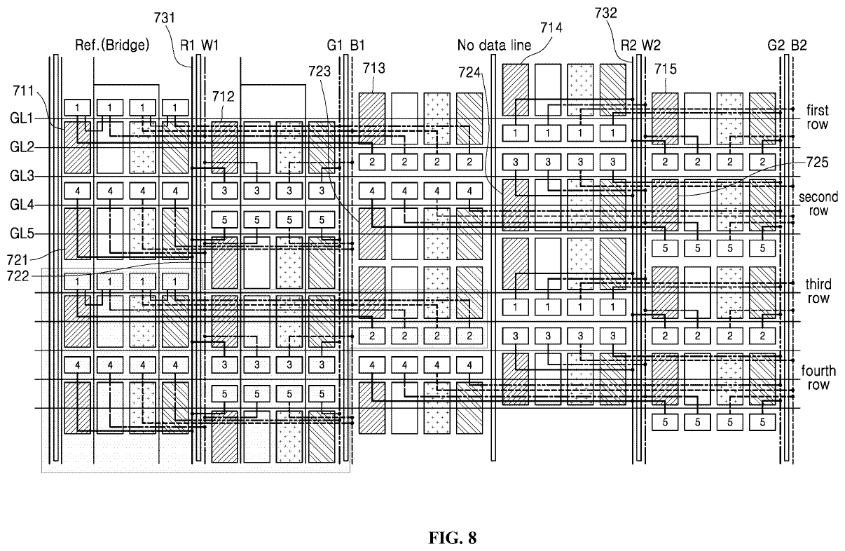

FIG. 7 is an example diagram illustrating a connection relationship between the sub-pixels emitting light of the same color and a gate line and sub-data lines in order to drive five pixels using two sub-data lines in a display device according to an embodiment of the present disclosure. FIG. 8 is an example diagram illustrating an arrangement relationship of sub-pixels operating using two sub-data lines in a display device according to an embodiment of the present disclosure.

FIG. 7 illustrates only specific sub-pixels R 711, 712, 713, 714, 715, 721, 722, 723, 724, and 725 among a plurality of sub-pixels. However, it is obvious that other sub-pixels G, B, and W are included in the display device, and FIG. 8 illustrates an arrangement relationship of the plurality of sub-pixels R, G, B, and W.

Referring to FIGS. 7 and 8, each sub-data line of the data line DL may be disposed between adjacent ones of a plurality of sub-pixels SP. For example, a first sub-data line 731 may be disposed on the right side of the sub-pixels R 711 and 721 of a first column, and a second sub-data line 732 may be disposed on the right side of the sub-pixels R 714 and 724 of a fourth column.

In addition, the first sub-data lines R1 and W1 may be disposed between the sub-pixels SP of the first column and the sub-pixels SP of the second column, the first sub-data lines G1 and B1 may be disposed between the sub-pixels SP of the second column and the sub-pixels SP of the third column, the second sub-data lines R2 and W2 may be disposed between the sub-pixels SP of the fourth column and the sub-pixels SP of the fourth column, and the second sub-data lines G2 and B2 may be disposed between the sub-pixels SP of the fifth column and the sub-pixels SP of the sixth column. In addition, in the present disclosure, the sub-pixels R, G, B, and W of the display panel 110 may operate even in a state (No data line state) in which the sub-data line is not disposed between the sub-pixels SP of the third column and the sub-pixels SP of the fourth column.

As shown in FIGS. 7 and 8, the first sub-data line 731 according to an embodiment may be disposed to supply a data voltage to the sub-pixels R 711, 712, and 713 of the first row and the sub-pixels R 721 and 722 of the second row, and the second sub-data line 732 may be disposed to supply a data voltage to the sub-pixels R 714 and 715 of the first row and the sub-pixels R 723, 724, and 725 of the second row. For example, a first data voltage as a red data voltage may be applied to the first sub-data line 731 and the second sub-data line 732.

According to an embodiment, the first gate line GL1 is disposed on one side (upper side in the drawing) in the column direction of the sub-pixels 711 and 714 of the first row and is connected to the driving circuit of each of the first sub-pixel 711 and the fourth sub-pixel 714 of the first row.

According to an embodiment, the second gate line GL2 is disposed on one side (upper side in the drawing) in the column direction of the sub-pixels 713 and 715 of the first row and is connected to the driving circuit of the third sub-pixel 713 of the first row.

According to an embodiment, the third gate line GL3 is disposed on the other side (lower side in the drawing) in the column direction of the sub-pixels 712 and 715 of the first row and is connected to the driving circuit of each of the first sub-pixel 713 and the fifth sub-pixel 715 of the first row.

According to an embodiment, the fourth gate line GL4 is disposed on one side (upper side in the drawing) in the column direction of the sub-pixels 721 and 724 of the second row and is connected to the driving circuit of each of the first sub-pixel 721 and the fourth sub-pixel 724 of the second row.

According to an embodiment, the fifth gate line GL5 is disposed on the other side (lower side in the drawing) in the column direction of the sub-pixels 722 and 723 of the second row, and is connected to the driving circuit of each of the second sub-pixels 722 and the second sub-pixels 723 of the second row.

FIGS. 7 and 8 illustrate that the first sub-data line 731 is disposed to supply the data voltage to the sub-pixels R 711, 712, and 713 of the first row and the sub-pixels R 721 and 722 of the second row, and the second sub-data line 732 is disposed to supply the data voltage to the sub-pixels R 714 and 715 of the first row and the sub-pixels R 723, 724, and 725 of the second row.

The plurality of data lines of the present disclosure may be disposed in the display panel 110 so that each of the plurality of data lines may divide into a plurality of sub-data lines and the data voltage is applied to a predetermined multiple of sub-pixels emitting light of the same color via each of the plurality of sub-data lines. In the display panel 110, a plurality of sub-data lines may be disposed such that a data voltage is applied to five sub-pixels emitting light of the same color being arranged in the same row via two sub-data lines. As described above, the display panel 110 according to the present disclosure may include a plurality of pixels, each of the plurality pixels including a plurality of sub-pixels emitting light of different colors, and may include a plurality of data lines via which the data voltage supplied from the data driver 120 is supplied to the plurality of pixels, and a plurality of gate lines via which the gate signal provided from the gate driver 130 is supplied to the plurality of pixels. Each of the plurality of data lines may include a plurality of divided sub-data lines. Each of the plurality of sub-data lines may be disposed in the display panel 110 such that the data voltage supplied from the data driver 120 is applied to five sub-pixels emitting light of the same color being arranged in the same row via two sub-data lines.

According to an embodiment, the plurality of sub-data lines may be disposed in the display panel 110 such that a data voltage is applied to three or two sub-pixels emitting light of the same color being arranged in the first row via the first sub-data line among the plurality of sub-data lines, or a data voltage is applied to two or three sub-pixels emitting light of the same color being arranged in the second row via the first sub-data line.

Accordingly, the display panel 110 may control the light emission order of the sub-pixels emitting light of the same color.

According to an embodiment, when the first gate voltage GATE1 at a turn-on level is applied via the first gate line GL1 in a state in which the data voltage is being supplied via the first sub-data line 731, the first gate signal is transmitted to the first sub-pixel 711 of the first row, and the data voltage may be charged into the first sub-pixel 711 of the first row, such that the first sub-pixel 711 of the first row emits light.

Thereafter, when the second gate voltage GATE2 at a turn-on level is applied via the second gate line GL2, the second gate signal is transmitted to the third sub-pixel 713 in the first row, and the data voltage may be charged into the third sub-pixel 713 in the first row, so that the third sub-pixel 713 in the first row emits light.

Thereafter, when the third gate voltage GATE3 at a turn-on level is applied via the third gate line GL3, the third gate signal is transmitted to the second sub-pixel 712 of the first row, and the data voltage may be charged into the second sub-pixel 712 of the first row, so that the second sub-pixel 712 of the first row emits light.

Thereafter, when the fourth gate voltage GATE4 at a turn-on level is applied via the fourth gate line GL4, the fourth gate signal is transmitted to the first sub-pixel 721 of the second row, and the data voltage may be charged into the first sub-pixel 721 of the second row, so that the first sub-pixel 721 of the second row emits light.

Thereafter, when the fifth gate voltage GATE5 at a turn-on level is applied via the fifth gate line GL5, the fifth gate signal is transmitted to the second sub-pixel 723 in the second row, and the data voltage may be charged into the second sub-pixel 722 in the second row, such that the second sub-pixel 722 in the second row emits light.

As described above, in the display panel 110, in a state in which the data voltage is being supplied via the first sub-data line 731, the sub-pixels 711, 712, and 713 of the first row and the sub-pixels 721 and 722 of the second row emit light in the order of the first sub-pixel 711 of the first row, the third sub-pixel 713 of the first row, the second sub-pixel 712 of the first row, the first sub-pixel 721 of the second row, and the second sub-pixel 722 of the second row.

FIGS. 7 and 8 illustrate a light emission order of sub-pixels in a case in which the first sub-data line 731 is disposed to supply a data voltage to the sub-pixels R 711, 712, and 713 of the first row and the sub-pixels R 721 and 722 of the second row, and the second sub-data line 732 is disposed to supply a data voltage to the sub-pixels R 714 and 715 of the first row and the sub-pixels R 723, 724, and 725 of the second row.

However, in the display panel 110 of the present disclosure, the first sub-data line 731 may be disposed to supply the data voltage to the sub-pixels R 711 and 712 of the first row and the sub-pixels R 721, 722, and 723 of the second row, and the second sub-data line 732 may be disposed to supply the data voltage to the sub-pixels R 713, 714, and 715 of the first row and the sub-pixels R 724 and 725 of the second row.

According to an embodiment, when the first gate voltage GATE1 at a turn-on level is applied via the first gate line GL1 in a state in which the data voltage is being supplied via the second sub-data line 732, the first gate signal is transmitted to the fourth sub-pixel 714 of the first row, and the data voltage may be charged into the fourth sub-pixel 714 of the first row, such that the fourth sub-pixel 714 of the first row emits light.

Thereafter, when the third gate voltage GATE3 at a turn-on level is applied via the third gate line GL3, the third gate signal is transmitted to the fifth sub-pixel 715 in the first row, and the data voltage may be charged into the fifth sub-pixel 715 in the first row, so that the fifth sub-pixel 715 in the first row emits light.

Thereafter, when the fourth gate voltage GATE4 at a turn-on level is applied via the fourth gate line GL4, the fourth gate signal is transmitted to the fourth sub-pixel 724 in the second row, and the data voltage may be charged into the fourth sub-pixel 724 in the second row, such that the fourth sub-pixel 724 in the second row emits light.

Thereafter, when the fifth gate voltage GATE5 at a turn-on level is applied via the fifth gate line GL5, the fifth gate signal is transmitted to the third sub-pixel 723 of the second row, and the data voltage may be charged to the third sub-pixel 723 of the second row, so that the third sub-pixel 723 of the second row emits light.

Thereafter, when the fifth gate voltage GATE5 at a turn-on level is applied via the fifth gate line GL5, the fifth gate signal is transmitted to the fifth sub-pixel 725 in the second row, and the data voltage may be charged into the fifth sub-pixel 725 in the second row, so that the fifth sub-pixel 722 in the second row emits light.

As described above, in the display panel 110, in a state in which the data voltage is being supplied via the second sub-data line 732, the sub-pixels 714 and 715 in the first row and the sub-pixels 723, 724, and 725 in the second row emit light in the order of the fourth sub-pixel 714 in the first row, the fifth sub-pixel 715 in the first row, the fourth sub-pixel 724 in the second row, the third sub-pixel 723 in the second row, and the fifth sub-pixel 725 in the second row.

As described above, in the present disclosure, five sub-pixels may operate using two sub-data lines, and such sub-pixels may be arranged in up, down, left, and right directions.

Although FIGS. 7 and 8 illustrate a light emission order of specific sub-pixel R 711, 712, 713, 714, 715, 721, 722, 723, 724, and 725, the technical idea of the present disclosure as described above is equally applicable to other sub-pixels G, B, and W. In addition, although FIGS. 7 and 8 illustrate the light emission of the sub-pixels SP in the first row and the second row, the technical idea of the present disclosure as described above is equally applicable to the third row and the fourth row.

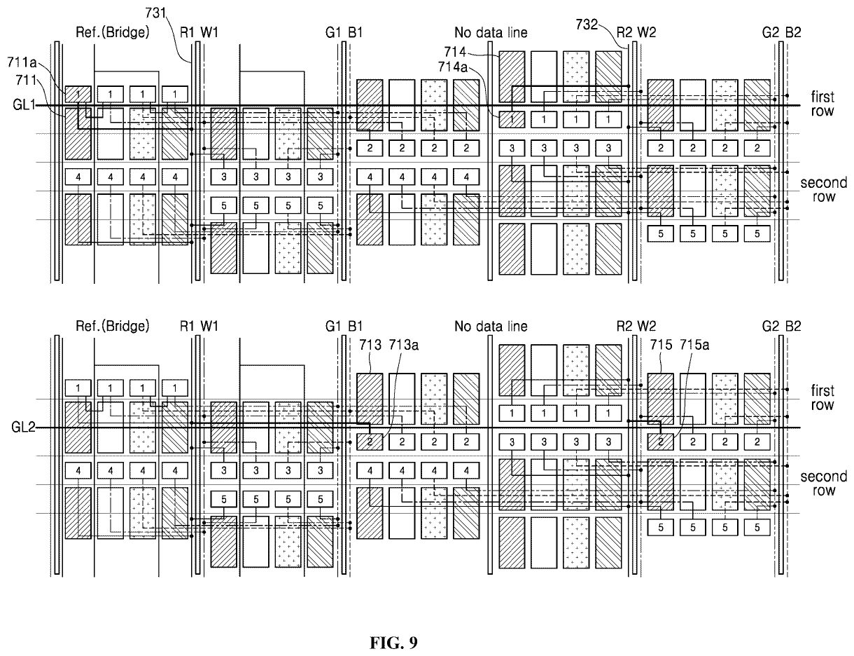

FIG. 9 is an example diagram illustrating a light emission state of a sub-pixel in a state in which a first gate voltage and a second gate voltage at a turn-on level are applied via a first gate line and a second gate line, respectively, according to an embodiment of the present disclosure.

According to an embodiment, the first sub-data line 731 may be disposed to supply a data voltage to the sub-pixels R 711, 712, and 713 of the first row and the sub-pixels R 721 and 722 of the second row, and the second sub-data line 732 may be disposed to supply a data voltage to the sub-pixels R 714 and 715 of the first row and the sub-pixels R 723, 724, and 725 of the second row.

According to an embodiment, when the first gate voltage GATE1 at a turn-on level is applied via the first gate line GL1, the first gate signal is transmitted to the driving circuit 711a of the first sub-pixel 711 of the first row, and the first gate voltage GATE1 may be charged into the driving circuit 711a of the first sub-pixel 711 of the first row. The first sub-pixel 711 of the first row emits light based on the first data voltage R1 applied via the first sub-data line 731.

In addition, when the first gate voltage GATE1 at a turn-on level is applied via the first gate line GL1, the first gate signal is transmitted to the driving circuit 714a of the fourth sub-pixel 714 in the first row, and the first gate voltage GATE1 may be charged into the driving circuit 714 a of the fourth sub-pixel 714 in the first row. The fourth sub-pixel 714 of the first row emits light based on the second data voltage R2 applied via the second sub-data line 732.

According to an embodiment, when the second gate voltage GATE2 at a turn-on level is applied via the second gate line GL2, the second gate signal is transmitted to the driving circuit 713a of the third sub-pixel 713 in the first row, and the first gate voltage GATE1 may be charged into the driving circuit 713a of the third sub-pixel 713 in the first row. The third sub-pixel 713 of the first row emits light based on the first data voltage R1 applied via the first sub-data line 731.

In addition, when the second gate voltage GATE2 at a turn-on level is applied via the second gate line GL2, the second gate signal is transmitted to the driving circuit 715a of the fifth sub-pixel 715 in the first row, and the second gate voltage GATE2 may be charged into the driving circuit 715a of the fifth sub-pixel 715 in the first row. The fifth sub-pixel 715 of the first row emits light based on the second data voltage R2 applied via the second sub-data line 732.

Although FIG. 9 discloses an operation order of specific sub-pixels R in each pixel PX, the technical idea of the present disclosure as described above is equally applicable to other sub-pixels G, B, and W in each pixel PX.

As described above, in the present disclosure, the sub-pixels R, G, B, and W of the display panel 110 may operate even in a state (No data line) in which the sub-data line is not disposed between the sub-pixels SP of the third column and the sub-pixels SP of the fourth column.

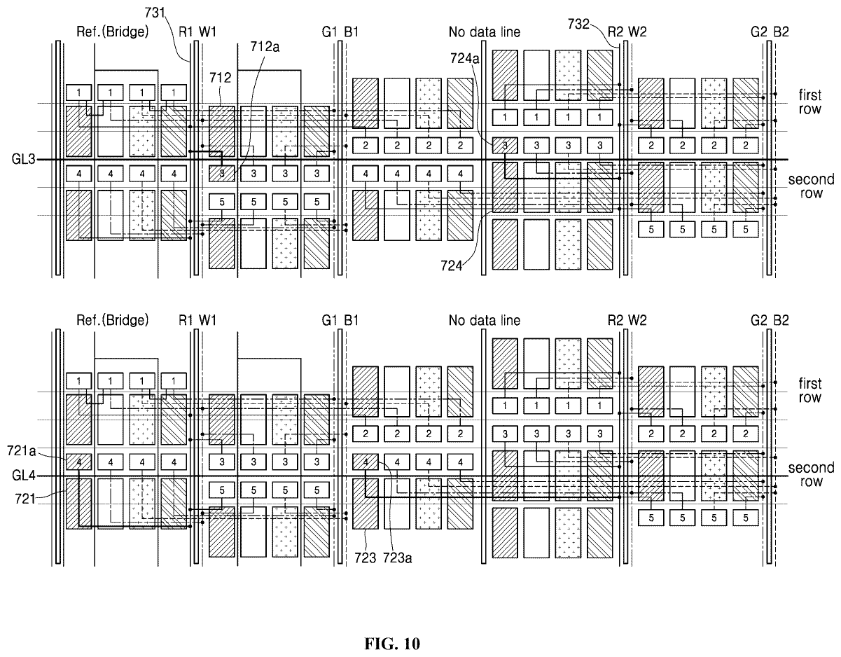

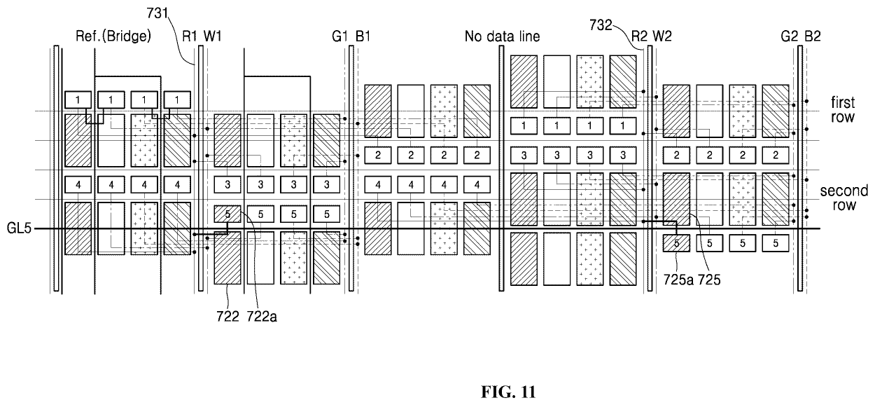

FIG. 10 is an example diagram illustrating a light emission state of a sub-pixel in a state in which a third gate voltage and a fourth gate voltage at a turn-on level are applied via a third gate line and a fourth gate line, respectively, according to an embodiment of the present disclosure.

According to an embodiment, the first sub-data line 731 may be disposed to supply a data voltage to the sub-pixels R 711, 712, and 713 of the first row and the sub-pixels R 721 and 722 of the second row, and the second sub-data line 732 may be disposed to supply a data voltage to the sub-pixels R 714 and 715 of the first row and the sub-pixels R 723, 724, and 725 of the second row.

According to an embodiment, when the third gate voltage GATE3 at a turn-on level is applied via the third gate line GL3, the third gate signal is transmitted to the driving circuit 712a of the second sub-pixel 712 of the first row, and the third gate voltage GATE3 may be charged into the driving circuit 712a of the second sub-pixel 712 of the first row. The second sub-pixel 712 of the first row emits light based on the first data voltage R1 applied via the first sub-data line 731.

In addition, when the third gate voltage GATE3 at a turn-on level is applied via the third gate line GL3, the third gate signal is transmitted to the driving circuit 724a of the fourth sub-pixel 724 in the second row, and the third gate voltage GATE3 may be charged into the driving circuit 724a of the fourth sub-pixel 724 in the second row. The fourth sub-pixel 724 of the second row emits light based on the second data voltage R2 applied via the second sub-data line 732.

According to an embodiment, when the fourth gate voltage GATE4 at a turn-on level is applied via the fourth gate line GL4, the fourth gate signal is transmitted to the driving circuit 721a of the first sub-pixel 721 of the second row, and the fourth gate voltage GATE4 may be charged into the driving circuit 721a of the first sub-pixel 721 of the second row. The first sub-pixel 721 of the second row emits light based on the first data voltage R1 applied via the first sub-data line 731.

In addition, when the fourth gate voltage GATE4 at a turn-on level is applied via the fourth gate line GL4, the fourth gate signal is transmitted to the driving circuit 723a of the third sub-pixel 723 in the second row, and the fourth gate voltage GATE4 may be charged into the driving circuit 723a of the third sub-pixel 723 in the second row. The third sub-pixel 723 of the second row emits light based on the second data voltage R2 applied via the second sub-data line 732.

FIG. 10 discloses an operation order of the specific sub-pixels R in each pixel PX. However, the technical idea of the present disclosure as described above is equally applicable to other sub-pixels G, B, and W in each pixel PX.

As described above, in the present disclosure, the sub-pixels R, G, B, and W of the display panel 110 may operate even in a state (No data line) in which the sub-data line is not disposed between the sub-pixels SP of the third column and the sub-pixels SP of the fourth column.

FIG. 11 is an example diagram illustrating a light emission state of a sub-pixel in a state in which a fifth gate voltage at a turn-on level is applied via a fifth gate line according to an embodiment of the present disclosure.

According to an embodiment, the first sub-data line 731 may be disposed to supply a data voltage to the sub-pixels R 711, 712, and 713 of the first row and the sub-pixels R 721 and 722 of the second row, and the second sub-data line 732 may be disposed to supply a data voltage to the sub-pixels R 714 and 715 of the first row and the sub-pixels R 723, 724, and 725 of the second row.

According to an embodiment, when the fifth gate voltage GATE5 at a turn-on level is applied via the fifth gate line GL5, the fifth gate signal is transmitted to the driving circuit 722a of the second sub-pixel 722 of the second row, and the fifth gate voltage GATE5 may be charged into the driving circuit 722a of the second sub-pixel 722 of the second row. The second sub-pixel 722 of the second row emits light based on the first data voltage R1 applied via the first sub-data line 731.

In addition, when the fifth gate voltage GATE5 at a turn-on level is applied via the fifth gate line GL5, the fifth gate signal is transmitted to the driving circuit 725a of the fifth sub-pixel 725 in the second row, and the fifth gate voltage GATE5 may be charged into the driving circuit 725a of the fifth sub-pixel 725 in the second row. The fifth sub-pixel 725 of the second row emits light based on the second data voltage R2 applied via the second sub-data line 732.

Although FIG. 11 discloses an operation order of specific sub-pixels R in each pixel PX, the technical idea of the present disclosure as described above is equally applicable to other sub-pixels G, B, and W in each pixel PX.

As described above, in the present disclosure, the sub-pixels R, G, B, and W of the display panel 110 may operate even in a state (No data line) in which the sub-data line is not disposed between the sub-pixels SP of the third column and the sub-pixels SP of the fourth column.

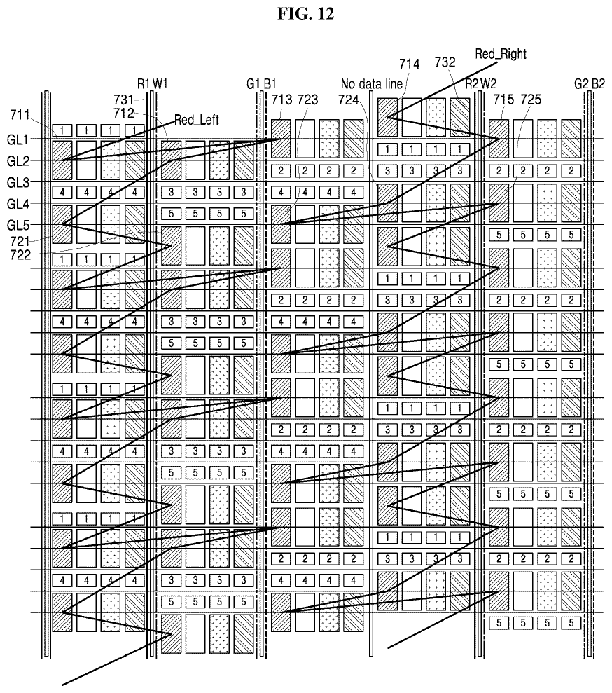

FIG. 12 is an example diagram illustrating an operation order of a pixel according to an embodiment of the present disclosure.

Referring to FIG. 12, in a state in which the data voltage is being supplied to the sub-pixels R via the first sub-data line 731 and the second sub-data line 732, respectively, the first gate voltage GATE1 at a turn-on level is applied via the first gate line GL1. Thus, the first gate signal is transmitted to the first sub-pixel 711 and the fourth sub-pixel 714 of the first row. The data voltage may be charged into the first sub-pixel 711 and the fourth sub-pixel 714 of the first row, so that the first sub-pixel 711 and the fourth sub-pixel 714 of the first row emit light.

Thereafter, when the second gate voltage GATE2 at a turn-on level is applied via the second gate line GL2, the second gate signal is transmitted to the third sub-pixel 713 in the first row and the fifth sub-pixel 715 in the first row. Thus, the data voltage may be charged into the third sub-pixel 713 and the fifth sub-pixel 715 of the first row, so that the third sub-pixel 713 and the fifth sub-pixel 715 of the first row emit light.

Thereafter, when the third gate voltage GATE3 at a turn-on level is applied via the third gate line GL3, the third gate signal is transmitted to the second sub-pixel 712 in the first row and the fourth sub-pixel 724 in the second row. Thus, the data voltage may be charged into the second sub-pixel 712 of the first row and the fourth sub-pixel 724 of the second row, and thus the second sub-pixel 712 of the first row and the fourth sub-pixel 724 of the second row emit light.

Thereafter, when the fourth gate voltage GATE4 at a turn-on level is applied via the fourth gate line GL4, the fourth gate signal is transmitted to the first sub-pixel 721 in the second row and the third sub-pixel 723 in the second row. Thus, a data voltage may be charged into the first sub-pixel 721 and the third sub-pixel 723 of the second row, and thus the first sub-pixel 721 and the third sub-pixel 723 of the second row emit light.

Thereafter, when the fifth gate voltage GATE5 at a turn-on level is applied via the fifth gate line GL5, the fifth gate signal is transmitted to the second sub-pixel 722 of the second row and the fifth sub-pixel 725 of the second row. Thus, the second sub-pixel 722 and the fifth sub-pixel 725 of the second row are charged with the data voltage, and thus the second sub-pixel 722 and the fifth sub-pixel 725 of the second row emit light.

The display panel 110 of the present disclosure may perform light emission by repeatedly performing the above-described emission pattern related to the sub-pixel.

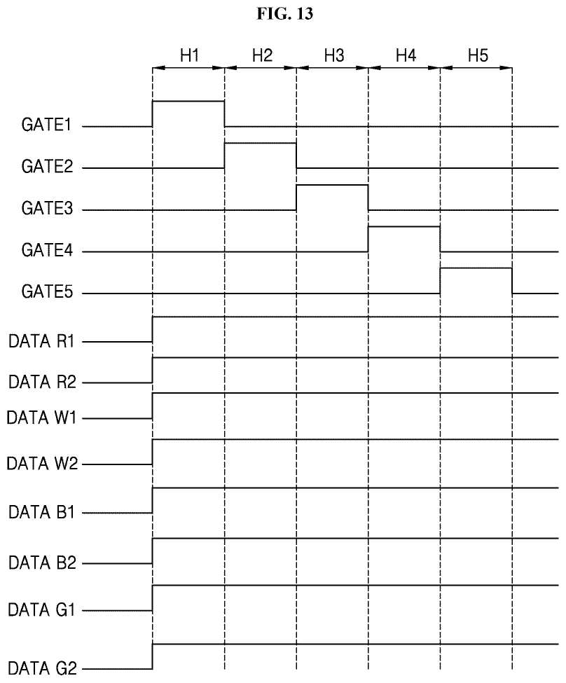

FIG. 13 is a timing diagram of a gate voltage and a data voltage when a display device according to an embodiment of the present disclosure displays a monochromatic still screen.

As illustrated in FIG. 13, the first gate voltage GATE1 is output via the first gate line GL1, the second gate voltage GATE2 is output via the second gate line GL2, the third gate voltage GATE3 is output via the third gate line GL3, the fourth gate voltage GATE4 is output via the fourth gate line GL4, and the fifth gate voltage GATE5 is output via the fifth gate line GL5.

In addition, the first data voltage DATA1 is output via the first data line DL1, the second data voltage DATA2 is output via the second data line DL2, the third data voltage DATA3 is output via the third data line DL3, the fourth data voltage DATA4 is output via the fourth data line DL4, and the fifth data voltage DATA5 is output via the fifth data line DL5.

As illustrated in FIG. 13, during the first horizontal period H1, the first gate voltage GATE1 is the gate high voltage, and the second gate voltage GATE2, the third gate voltage GATE3, the fourth gate voltage GATE4, and the fifth gate voltage GATE5 are the gate low voltages. In addition, during the first horizontal period H1, each of the first data voltage DATA1 to the fifth data voltage DATA5 may be a data voltage of a predetermined level for implementing a predetermined grayscale.

Accordingly, during the first horizontal period H1, all of the switching transistors respectively connected to the plurality of first sub-pixels R1, W1, B1, and G1 arranged in the first column and the plurality of fourth sub-pixels R2, W2, B2, and G2 arranged in the fourth column in the odd-numbered row odd are turned on.

Accordingly, during the first horizontal period H1, in the odd-numbered row odd, the data voltage DATA R1 may be charged into the first sub-pixels R1 and 711 arranged in the first column, the data voltage DATA R2 may be charged into the fourth sub-pixels R2 and 714 arranged in the fourth column, the data voltage DATA W1 may be charged into the first sub-pixel W1 arranged in the first column, the data voltage DATA W2 may be charged into the fourth sub-pixel W2 arranged in the fourth column, the data voltage DATA B1 may be charged into the first sub-pixel B1 arranged in the first column, and the data voltage DATA B1 may be charged into the fourth sub-pixel B2 arranged in the fourth column. The data voltage DATA G1 may be charged into the first sub-pixel G1 arranged in the first column, and the data voltage DATA G2 may be charged into the fourth sub-pixel G2 arranged in the fourth column.

As illustrated in FIG. 13, during the second horizontal period H2, the second gate voltage GATE2 is the gate high voltage, and the first gate voltage GATE1, the third gate voltage GATE3, the fourth gate voltage GATE4, and the fifth gate voltage GATE5 are the gate low voltages. In addition, during the second horizontal period H2, each of the first data voltage DATA1 to the fifth data voltage DATA5 may be a data voltage of a predetermined level for implementing a predetermined grayscale.

Accordingly, during the second horizontal period H2, all of the switching transistors respectively connected to the plurality of third sub-pixels R1, W1, B1, and G1 arranged in the third column and the plurality of fifth sub-pixels R2, W2, B2, and G2 arranged in the fifth column in the odd-numbered row odd are turned on.

Accordingly, during the second horizontal period H2, in the odd-numbered row odd, the data voltage DATA R1 may be charged into the third sub-pixel R1 713 arranged in the third column, the data voltage DATA R2 may be charged into the fifth sub-pixel R2 715 arranged in the fifth column, the data voltage DATA W1 may be charged into the third sub-pixel W1 arranged in the third column, the data voltage DATA W2 may be charged into the fifth sub-pixel W2 arranged in the fifth column, the data voltage DATA B1 may be charged into the third sub-pixel B1 arranged in the third column, and the data voltage DATA B2 may be charged into the fifth sub-pixel B2 arranged in the fifth column. The data voltage DATA G1 may be charged into the third sub-pixel G1 arranged in the third column, and the data voltage DATA G2 may be charged into the fifth sub-pixel G2 arranged in the fifth column.

As illustrated in FIG. 13, during the third horizontal period H3, the third gate voltage GATE3 is the gate high voltage, and the first gate voltage GATE1, the second gate voltage GATE2, the fourth gate voltage GATE4, and the fifth gate voltage GATE5 are the gate low voltages. In addition, during the third horizontal period H3, each of the first data voltage DATA1 to the fifth data voltage DATA5 may be a data voltage of a predetermined level for implementing a predetermined grayscale.

Accordingly, during the third horizontal period H3, all of the switching transistors respectively connected to the plurality of second sub-pixels R1, W1, B1, and G1 arranged in the second column in the odd-numbered row odd and the plurality of fourth sub-pixels R2, W2, B2, and G2 arranged in the fourth column in the even-numbered row even are turned on.

Accordingly, during the third horizontal period H3, in the odd-numbered row odd, the data voltage DATA R1 may be charged into the second sub-pixels R1 and 712 arranged in the second column, the data voltage DATA R2 may be charged into the fourth sub-pixel R2 arranged in the fourth column in the even-numbered row even, the data voltage DATA W1 may be charged into the second sub-pixel W1 arranged in the second column in the odd-numbered row odd, the data voltage DATA W2 may be charged into the fourth sub-pixel W2 arranged in the fourth column in the even-numbered row even, and the data voltage DATA B1 may be charged into the second sub-pixel B1 arranged in the second column in the odd-numbered row odd The data voltage DATA B2 may be charged into the fourth sub-pixel B2 arranged in the fourth column in the even-numbered row even, the data voltage DATA G1 may be charged into the second sub-pixel G1 arranged in the second column in the odd-numbered row odd, and the data voltage DATA G2 may be charged into the fourth sub-pixel G2 arranged in the fourth column in the even-numbered row even.

As illustrated in FIG. 13, in the fourth horizontal period H4, the fourth gate voltage GATE4 is the gate high voltage, and the first gate voltage GATE1, the second gate voltage GATE2, the third gate voltage GATE3, and the fifth gate voltage GATE5 are the gate low voltages. In addition, in the fourth horizontal period H4, each of the first data voltage DATA1 to the fifth data voltage DATA5 may be a data voltage of a predetermined level for implementing a predetermined gray scale.

Accordingly, during the fourth horizontal period H4, all of the switching transistors respectively connected to the plurality of first sub-pixels R1, W1, B1, and G1 arranged in the first column and the plurality of third sub-pixels R2, W2, B2, and G2 arranged in the third column in the even-numbered row even are turned on.

Accordingly, during the fourth horizontal period H4, in the even-numbered row even, the data voltage DATA R1 may be charged into the first sub-pixels R1 and 721 arranged in the first column, the data voltage DATA R2 may be charged into the third sub-pixels R2 and 723 arranged in the third column, the data voltage DATA W1 may be charged into the first sub-pixel W1 arranged in the first column, the data voltage DATA W2 may be charged into the third sub-pixel W2 arranged in the third column, the data voltage DATA B1 may be charged into the first sub-pixel B1 arranged in the first column, and the data voltage DATA B1 may be charged into the third sub-pixel B2 arranged in the third column. The data voltage DATA G1 may be charged into the first sub-pixel G1 arranged in the first column, and the data voltage DATA G2 may be charged into the third sub-pixel G2 arranged in the third column.

As illustrated in FIG. 13, during the fifth horizontal period H5, the fifth gate voltage GATE5 is the gate high voltage, and the first gate voltage GATE1, the second gate voltage GATE2, the third gate voltage GATE3, and the fourth gate voltage GATE4 are the gate low voltages. During the fifth horizontal period H5, each of the first data voltage DATA1 to the fifth data voltage DATA5 may be a data voltage of a predetermined level for implementing a predetermined grayscale.

Accordingly, during the fifth horizontal period H5, all of the switching transistors respectively connected to the plurality of second sub-pixels R1, W1, B1, and G1 arranged in the second column and the plurality of fifth sub-pixels R2, W2, B2, and G2 arranged in the fifth column in the even-numbered row even are turned on.

Accordingly, during the fifth horizontal period H5, in the even-numbered row even, the data voltage DATA R1 may be charged into the second sub-pixels R1 and 722 arranged in the second column, the data voltage DATA R2 may be charged into the fifth sub-pixels R2 and 725 arranged in the fifth column, the data voltage DATA W1 may be charged into the second sub-pixel W1 arranged in the second column, the data voltage DATA W2 may be charged into the fifth sub-pixel W2 arranged in the fifth column, the data voltage DATA B1 may be charged into the second sub-pixel B1 arranged in the second column, and the data voltage DATA B2 may be charged into the fifth sub-pixel B2 arranged in the fifth column. The data voltage DATA G1 may be charged into the second sub-pixel G1 arranged in the second column, and the data voltage DATA G2 may be charged into the fifth sub-pixel G2 arranged in the fifth column.

As described above, when the display device 100 according to an embodiment of the present disclosure displays a monochromatic still screen, each of the first to fifth data voltages VDATA1 to VDATA5 may have the same level during the first to fifth horizontal periods H1 to H5, that is, during one frame. Accordingly, each of the first to fifth data voltages is not subjected to the data voltage change (data transition) during one frame.

The display panel and the display device according to various aspects and embodiments of the present disclosure may be described as follows.

One embodiment of the present disclosure provides a display panel comprising: a plurality of pixels, each of the plurality of pixels including a plurality of sub-pixels emitting light of different colors; a plurality of data lines disposed to supply a data voltage to the plurality of pixels; a plurality of gate lines disposed to supply a gate signal to the plurality of pixels; and a plurality of sub-data lines into which each of the plurality of data lines divides, wherein the plurality of sub-data lines are disposed such that the data voltage is applied to five sub-pixels emitting light of the same color being arranged in the same row via two sub-data lines.

In accordance with some embodiments of the display panel of the present disclosure, the plurality of sub-data lines are disposed such that the data voltage is applied to three or two sub-pixels emitting light of the same color being arranged in a first row via a first sub-data line among the plurality of sub-data lines or the data voltage is applied to two or three sub-pixels emitting light of the same color being arranged in a second row adjacent to the first row in a column direction via the first sub-data line.

In accordance with some embodiments of the display panel of the present disclosure, the plurality of sub-data lines are disposed such that when the first sub-data line applies the data voltage to three sub-pixels emitting light of the same color being arranged in the first row, a second sub-data line among the plurality of sub-data lines applies the data voltage to two sub-pixels emitting light of the same color being arranged in the first row.

In accordance with some embodiments of the display panel of the present disclosure, the first sub-data line applies the data voltage to three sub-pixels emitting light of the same color being arranged in the first row and to two sub-pixels emitting light of the same color being arranged in the second row adjacent to the first row in a column direction.

In accordance with some embodiments of the display panel of the present disclosure, the first sub-data line is disposed between a first pixel and a second pixel sequentially arranged in a row direction from one side of a row of the plurality of pixels.

In accordance with some embodiments of the display panel of the present disclosure, the plurality of sub-data lines are disposed such that when the first sub-data line applies the data voltage to two sub-pixels emitting light of the same color being arranged in the first row, a second sub-data line among the plurality of sub-data lines applies the data voltage to three sub-pixels emitting light of the same color being arranged in the first row.

In accordance with some embodiments of the display panel of the present disclosure, the second sub-data line applies the data voltage to two sub-pixels emitting light of the same color being arranged in the first row and to three sub-pixels emitting light of the same color being arranged in the second row adjacent to the first row in a column direction.

In accordance with some embodiments of the display panel of the present disclosure, the second sub-data line is disposed between a fourth pixel and a fifth pixel sequentially arranged from one side of a row of the plurality of pixels.

In accordance with some embodiments of the display panel of the present disclosure, the display panel further comprises a plurality of driving circuits arranged in a first column, wherein each of the plurality of driving circuits is disposed on one side in a column direction of each sub-pixel disposed in the first column and in each row and is connected to each sub-pixel, wherein each of the plurality of driving circuits is configured to drive each sub-pixel disposed in the first column and in each row.

In accordance with some embodiments of the display panel of the present disclosure, the display panel further comprises a plurality of driving circuits arranged in each of second to fourth columns, wherein the first to fourth columns are sequentially arranged in a row direction, wherein each of the plurality of driving circuits arranged in each of the second to fourth columns is disposed on the other side in the column direction of each sub-pixel disposed in each of the second to fourth columns and disposed in each of first and third rows and is connected to each sub-pixel, wherein each of the plurality of driving circuits arranged in each of the second to fourth columns is configured to drive each sub-pixel disposed in each of the second to fourth columns and disposed in each of the first and third rows.

In accordance with some embodiments of the display panel of the present disclosure, each of the plurality of driving circuits arranged in each of the second to fourth columns is disposed on one side in the column direction of each sub-pixel disposed in each of the second to fourth columns and disposed in each of second and fourth rows and is connected to each sub-pixel, wherein each of the plurality of driving circuits arranged in each of the second to fourth columns is configured to drive each sub-pixel disposed in each of the second to fourth columns and disposed in each of the second and fourth rows.

In accordance with some embodiments of the display panel of the present disclosure, the sub-pixels emitting light of the same color and respectively disposed in the first to fourth rows are arranged in a row direction in a staggered manner in a plan view of the display panel, wherein the driving circuits corresponding to the sub-pixels emitting light of the same color and respectively disposed in the first to fourth rows are arranged in a row direction in a staggered manner in the plan view.

In accordance with some embodiments of the display panel of the present disclosure, the first sub-data line applies the data voltage to three sub-pixels emitting light of the same color being arranged in the first row and to two sub-pixels emitting light of the same color being arranged in the second row, wherein the second sub-data line applies the data voltage to two sub-pixels emitting light of the same color being arranged in the first row and to three sub-pixels emitting light of the same color being arranged in the second row, wherein the gate signal is supplied to the sub-pixel disposed in a first column of the first row via a first gate line among the plurality of gate lines, wherein the gate signal is supplied to a sub-pixel disposed in a third column of the first row via a second gate line among the plurality of gate lines, wherein the gate signal is supplied to a sub-pixel disposed in a second column of the first row via a third gate line among the plurality of gate lines, wherein the gate signal is supplied to a sub-pixel disposed in the first column of the second row via a fourth gate line among the plurality of gate lines, wherein the gate signal is supplied to a sub-pixel disposed in the second column of the second row via a fifth gate line among the plurality of gate lines.

In accordance with some embodiments of the display panel of the present disclosure, the first sub-data line applies the data voltage to three sub-pixels emitting light of the same color being arranged in the first row and to two sub-pixels emitting light of the same color being arranged in the second row, wherein the second sub-data line applies the data voltage to two sub-pixels emitting light of the same color being arranged in the first row and to three sub-pixels emitting light of the same color being arranged in the second row, wherein the gate signal is supplied to a sub-pixel disposed in a fourth column of the first row via a first gate line among the plurality of gate lines, wherein the gate signal is supplied to a sub-pixel disposed in a fifth column of the first row via a second gate line among the plurality of gate lines, wherein the gate signal is supplied to a sub-pixel disposed in a fourth column of the second row via a third gate line among the plurality of gate lines, wherein the gate signal is supplied to a sub-pixel disposed in the third column of the second row via a fourth gate line among the plurality of gate lines, wherein the gate signal is supplied to a sub-pixel disposed in the fifth column of the second row via a fifth gate line among the plurality of gate lines.

In accordance with some embodiments of the display panel of the present disclosure, the first sub-data line applies the data voltage to two sub-pixels emitting light of the same color being arranged in the first row and to three sub-pixels emitting light of the same color being arranged in the second row, wherein the second sub-data line applies the data voltage to three sub-pixels emitting light of the same color being arranged in the first row and to two sub-pixels emitting light of the same color being arranged in the second row, wherein the gate signal is supplied to a sub-pixel disposed in a first column of the first row via a first gate line among the plurality of gate lines, wherein the gate signal is supplied to a sub-pixel disposed in a second column of the first row via a second gate line among the plurality of gate lines, wherein the gate signal is supplied to a sub-pixel disposed in the first column of the second row via a third gate line among the plurality of gate lines, wherein the gate signal is supplied to a sub-pixel disposed in a third column of the second row via a fourth gate line among the plurality of gate lines, wherein the gate signal is supplied to a sub-pixel disposed in the second column of the second row via a fifth gate line among the plurality of gate lines.

In accordance with some embodiments of the display panel of the present disclosure, the first sub-data line applies the data voltage to two sub-pixels emitting light of the same color being arranged in the first row and to three sub-pixels emitting light of the same color being arranged in the second row, wherein the second sub-data line applies the data voltage to three sub-pixels emitting light of the same color being arranged in the first row and to two sub-pixels emitting light of the same color being arranged in the second row, wherein the gate signal is supplied to a sub-pixel disposed in a third column of the first row via a first gate line among the plurality of gate lines, wherein the gate signal is supplied to a sub-pixel disposed in a fifth column of the first row via a second gate line among the plurality of gate lines, wherein the gate signal is supplied to a sub-pixel disposed in a fourth column of the first row via a third gate line among the plurality of gate lines, wherein the gate signal is supplied to a sub-pixel disposed in the fourth column of the second row via a fourth gate line among the plurality of gate lines, wherein the gate signal is supplied to a sub-pixel disposed in the fifth column of the second row via a fifth gate line among the plurality of gate lines.

In accordance with some embodiments of the display panel of the present disclosure, a plurality of first sub-pixels included in the plurality of pixels are red sub-pixels arranged in the same column, wherein a plurality of second sub-pixels included in the plurality of pixels are white sub-pixels arranged in the same column, wherein a plurality of third sub-pixels included in the plurality of pixels are blue sub-pixels arranged in the same column, wherein a plurality of fourth sub-pixels included in the plurality of pixels are green sub-pixels arranged in the same column.

In accordance with some embodiments of the display panel of the present disclosure, a predetermined multiple of sub-pixels emitting light of the same color operate using a single sub-data line, wherein the predetermined multiple is 2.5.

In accordance with some embodiments of the display panel of the present disclosure, each of the plurality of sub-pixels includes a switching transistor, a driving transistor, a storage capacitor, a sensing transistor, and a light-emitting element.

Another aspect of the present disclosure provides a display device comprising: a display panel in which a plurality of pixels are disposed, wherein each of the plurality of pixels includes a plurality of sub-pixels emitting light of different colors; a data driver configured to supply a data voltage to the plurality of pixels via a plurality of data lines; and a gate driver configured to supply a gate signal to the plurality of pixels via a plurality of gate lines, wherein the display panel includes the plurality of data lines and the plurality of gate lines, wherein each of the plurality of data lines divides into a plurality of sub-data lines, wherein the plurality of sub-data lines are disposed such that the data voltage is applied to five sub-pixels emitting light of the same color being arranged in the same row via two sub-data lines.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

What is claimed is:

1. A display panel comprising:
a plurality of pixels, each of the plurality of pixels including a plurality of sub-pixels emitting light of different colors;
a plurality of data lines that supply a data voltage to the plurality of pixels;
a plurality of gate lines that supply a gate signal to the plurality of pixels; and
a plurality of sub-data lines into which each of the plurality of data lines divides,
wherein the plurality of sub-data lines are disposed such that the data voltage is applied to five sub-pixels from the plurality of sub-pixels that emit light of a same color and are arranged in a same row via two sub-data lines.

2. The display panel of claim 1, wherein the plurality of sub-data lines are disposed such that the data voltage is applied to three or two sub-pixels from the plurality of sub-pixels that emit light of a same color and are arranged in a first row via a first sub-data line among the plurality of sub-data lines or the data voltage is applied to two or three sub-pixels from the plurality of sub-pixels that emit light of a same color and are arranged in a second row adjacent to the first row in a column direction via the first sub-data line.

3. The display panel of claim 2, wherein the plurality of sub-data lines are disposed such that when the first sub-data line applies the data voltage to three sub-pixels from the plurality of sub-pixels that emit light of a same color and are arranged in the first row, a second sub-data line among the plurality of sub-data lines applies the data voltage to two sub-pixels from the plurality of sub-pixels that emit light of a same color and are arranged in the first row.

4. The display panel of claim 3, wherein the first sub-data line applies the data voltage to three sub-pixels from the plurality of sub-pixels that emit light of a same color and are arranged in the first row and to two sub-pixels from the plurality of sub-pixels that emit light of a same color and are arranged in the second row that is adjacent to the first row in a column direction.

5. The display panel of claim 4, wherein the first sub-data line is between a first pixel and a second pixel sequentially arranged in a row direction from one side of a row of the plurality of pixels.

6. The display panel of claim 2, wherein the plurality of sub-data lines are disposed such that when the first sub-data line applies the data voltage to two sub-pixels from the plurality of sub-pixels that emit light of a same color and arranged in the first row, a second sub-data line among the plurality of sub-data lines applies the data voltage to three sub-pixels from the plurality of sub-pixels that emit light of a same color and arranged in the first row.

7. The display panel of claim 6, wherein the second sub-data line applies the data voltage to two sub-pixels from the plurality of sub-pixels that emit light of a same color and arranged in the first row and to three sub-pixels from the plurality of sub-pixels that emit light of a same color and arranged in the second row adjacent to the first row in a column direction.

8. The display panel of claim 7, wherein the second sub-data line is between a fourth pixel and a fifth pixel sequentially arranged from one side of a row of the plurality of pixels.

9. The display panel of claim 1, wherein the display panel further comprises:
a plurality of driving circuits arranged in a first column,
wherein each of the plurality of driving circuits is on one side in a column direction of each of the plurality of sub-pixels disposed in the first column and in each row and is connected to each of the plurality of sub-pixels, and
wherein each of the plurality of driving circuits is configured to drive each of the plurality of sub-pixels disposed in the first column and in each row.

10. The display panel of claim 9, wherein the display panel further comprises a plurality of driving circuits arranged in each of a second column to a fourth column,
wherein the first column to the fourth column are sequentially arranged in a row direction,
wherein each of the plurality of driving circuits arranged in each of the second column to the fourth column is disposed on another side in the column direction of each of the plurality of sub-pixels disposed in each of the second column to the fourth column and disposed in each of a first row and a third row and is connected to each of the plurality of sub-pixels, and
wherein each of the plurality of driving circuits arranged in each of the second column to the fourth column is configured to drive each of the plurality of sub-pixels disposed in each of the second column to the fourth column and disposed in each of the first row and the third row.

11. The display panel of claim 10, wherein each of the plurality of driving circuits arranged in each of the second column to the fourth column is disposed on one side in the column direction of each of the plurality of sub-pixels disposed in each of the second column to the fourth column and disposed in each of a second row and a fourth row and is connected to each of the plurality of sub-pixels, and
wherein each of the plurality of driving circuits arranged in each of the second column to the fourth column is configured to drive each of the plurality of sub-pixels disposed in each of the second column to the fourth column and disposed in each of the second row and the fourth row.

12. The display panel of claim 11, wherein sub-pixels from the plurality of sub-pixels that emit light of a same color and respectively disposed in the first row to the fourth row are arranged in a row direction in a staggered manner in a plan view of the display panel, and
wherein the driving circuits corresponding to the sub-pixels emitting light of the same color and respectively disposed in the first row to the fourth row are arranged in a row direction in a staggered manner in the plan view.

13. The display panel of claim 3, wherein if the first sub-data line applies the data voltage to three sub-pixels from the plurality of sub-pixels that emit light of a same color and arranged in the first row and to two sub-pixels from the plurality of sub-pixels that emit light of a same color being and in the second row, and if the second sub-data line applies the data voltage to two sub-pixels from the plurality of sub-pixels that emit light of a same color and arranged in the first row and to three sub-pixels from the plurality of sub-pixels that emit light of a same color and arranged in the second row,
the gate signal is supplied to the sub-pixel disposed in a first column of the first row via a first gate line among the plurality of gate lines,
the gate signal is supplied to a sub-pixel disposed in a third column of the first row via a second gate line among the plurality of gate lines,
the gate signal is supplied to a sub-pixel disposed in a second column of the first row via a third gate line among the plurality of gate lines,
the gate signal is supplied to a sub-pixel disposed in the first column of the second row via a fourth gate line among the plurality of gate lines, and
the gate signal is supplied to a sub-pixel disposed in the second column of the second row via a fifth gate line among the plurality of gate lines.

14. The display panel of claim 3, wherein if the first sub-data line applies the data voltage to three sub-pixels from the plurality of sub-pixels that emit light of a same color and arranged in the first row and to two sub-pixels from the plurality of sub-pixels that emit light of a same color and arranged in the second row, and if the second sub-data line applies the data voltage to two sub-pixels from the plurality of sub-pixels that emit light of a same color and arranged in the first row and to three sub-pixels from the plurality of sub-pixels that emit light of a same color and arranged in the second row,
the gate signal is supplied to a sub-pixel disposed in a fourth column of the first row via a first gate line among the plurality of gate lines,
the gate signal is supplied to a sub-pixel disposed in a fifth column of the first row via a second gate line among the plurality of gate lines,
the gate signal is supplied to a sub-pixel disposed in a fourth column of the second row via a third gate line among the plurality of gate lines,
the gate signal is supplied to a sub-pixel disposed in the third column of the second row via a fourth gate line among the plurality of gate lines, and
the gate signal is supplied to a sub-pixel disposed in the fifth column of the second row via a fifth gate line among the plurality of gate lines.

15. The display panel of claim 3, wherein if the first sub-data line applies the data voltage to two sub-pixels from the plurality of sub-pixels that emit light of a same color and arranged in the first row and to three sub-pixels from the plurality of sub-pixels that emit light of a same color and arranged in the second row, and if the second sub-data line applies the data voltage to three sub-pixels from the plurality of sub-pixels that emit light of a same color and arranged in the first row and to two sub-pixels from the plurality of sub-pixels that emit light of a same color and arranged in the second row,
the gate signal is supplied to a sub-pixel disposed in a first column of the first row via a first gate line among the plurality of gate lines,
the gate signal is supplied to a sub-pixel disposed in a second column of the first row via a second gate line among the plurality of gate lines,
the gate signal is supplied to a sub-pixel disposed in the first column of the second row via a third gate line among the plurality of gate lines,
the gate signal is supplied to a sub-pixel disposed in a third column of the second row via a fourth gate line among the plurality of gate lines, and
the gate signal is supplied to a sub-pixel disposed in the second column of the second row via a fifth gate line among the plurality of gate lines.

16. The display panel of claim 3, wherein if the first sub-data line applies the data voltage to two sub-pixels from the plurality of sub-pixels that emit light of a same color and arranged in the first row and to three sub-pixels from the plurality of sub-pixels that emit light of a same color and arranged in the second row, and if the second sub-data line applies the data voltage to three sub-pixels from the plurality of sub-pixels that emit light of a same color and arranged in the first row and to two sub-pixels from the plurality of sub-pixels that emit light of a same color and arranged in the second row,
the gate signal is supplied to a sub-pixel disposed in a third column of the first row via a first gate line among the plurality of gate lines,
the gate signal is supplied to a sub-pixel disposed in a fifth column of the first row via a second gate line among the plurality of gate lines,
the gate signal is supplied to a sub-pixel disposed in a fourth column of the first row via a third gate line among the plurality of gate lines,
the gate signal is supplied to a sub-pixel disposed in the fourth column of the second row via a fourth gate line among the plurality of gate lines, and
the gate signal is supplied to a sub-pixel disposed in the fifth column of the second row via a fifth gate line among the plurality of gate lines.

17. The display panel of claim 1, wherein a plurality of first sub-pixels included in the plurality of pixels are red sub-pixels arranged in a same column,
wherein a plurality of second sub-pixels included in the plurality of pixels are white sub-pixels arranged in a same column,
wherein a plurality of third sub-pixels included in the plurality of pixels are blue sub-pixels arranged in a same column, and
wherein a plurality of fourth sub-pixels included in the plurality of pixels are green sub-pixels arranged in a same column.

18. The display panel of claim 1, wherein a predetermined multiple of sub-pixels from the plurality of sub-pixels that emit light of a same color operate using a single sub-data line, wherein the predetermined multiple is 2.5.

19. The display panel of claim 1, wherein each of the plurality of sub-pixels includes a switching transistor, a driving transistor, a storage capacitor, a sensing transistor, and a light-emitting element.

20. A display device comprising:
a display panel including a plurality of pixels, each of the plurality of pixels includes a plurality of sub-pixels emitting light of different colors;
a data driver configured to supply a data voltage to the plurality of pixels via a plurality of data lines; and
a gate driver configured to supply a gate signal to the plurality of pixels via a plurality of gate lines,
wherein the display panel comprises the plurality of data lines and the plurality of gate lines,
wherein each of the plurality of data lines divides into a plurality of sub-data lines, and
wherein the plurality of sub-data lines are disposed such that the data voltage is applied to five sub-pixels from the plurality of sub-pixels that emit light of a same color and arranged in a same row via two sub-data lines.
